(19) United States
(12) Patent Application Publication
(10) Pub. No.: US 2026/0105961 A1
(43) Pub. Date: Apr. 16, 2026

(54) NONVOLATILE MEMORY WITH MULTI-CELL WEIGHT STRUCTURE

(71) Applicant: Sandisk Technologies, Inc., Milpitas, CA (US)

(72) Inventors: Ming Wang, Shanghai (CN); Liang Li, Shanghai (CN); Xuan Tian, Shanghai (CN)

(73) Assignee: Sandisk Technologies, Inc., Milpitas, CA (US)

(21) Appl. No.: 18/916,844

(22) Filed: Oct. 16, 2024

(51) Int. Cl. G11C 16/04; G06F 17/16; G11C 16/08; G11C 16/10; G11C 16/24; G11C 16/26; H01L 25/065; H10B 43/10; H10B 43/27; H10B 43/35

(52) U.S. Cl. CPC G11C 16/0483; G06F 17/16; G11C 16/08; G11C 16/10; G11C 16/24; G11C 16/26; H10B 43/10; H10B 43/27; H10B 43/35; H10W 90/00; H10W 90/24

(57) ABSTRACT

A nonvolatile storage apparatus includes nonvolatile memory cells, bit lines connected to the nonvolatile memory cells and one or more control circuits connected to the nonvolatile memory cells and the bit lines. The one or more control circuits are configured to store weights in the nonvolatile memory cells. Each individual weight is stored by a group of two or more nonvolatile memory cells.

### BACKGROUND

The present disclosure relates to nonvolatile storage.

Semiconductor memory is widely used in various electronic devices such as cellular telephones, digital cameras, personal digital assistants, medical electronics, mobile computing devices, servers, solid state drives, non-mobile computing devices and other devices. Semiconductor memory may comprise nonvolatile memory or volatile memory. Nonvolatile memory allows information to be stored and retained even when the nonvolatile memory is not connected to a source of power (e.g., a battery). One example of nonvolatile memory is flash memory (e.g., NAND-type and NOR-type flash memory).

Users of nonvolatile memory can program (e.g., write) data to the nonvolatile memory and later read that data back. For example, a digital camera may take a photograph and store the photograph in nonvolatile memory. Later, a user of the digital camera may view the photograph by having the digital camera read the photograph from the nonvolatile memory. Because users often rely on the data they store, it is important to users of nonvolatile memory that the nonvolatile memory operate reliably (e.g., user be able to successfully read back data stored in the nonvolatile memory).

In some cases, nonvolatile memory may be used in machine learning (ML) or artificial intelligence (AI) applications. Nonvolatile memory may have some advantages over volatile memory for such applications.

### BRIEF DESCRIPTION OF THE DRAWINGS

Like-numbered elements refer to common components in the different figures.

FIG. 1 is a block diagram depicting one embodiment of a storage system.

FIG. 2A is a block diagram of one embodiment of a memory die.

FIG. 2B is a block diagram of one embodiment of an integrated memory assembly.

FIGS. 3A and 3B depict different embodiments of integrated memory assemblies.

FIG. 4 is a perspective view of a portion of one embodiment of a monolithic three dimensional NAND memory structure.

FIG. 4A is a block diagram of one embodiment of a memory structure having two planes.

FIG. 4B depicts a top view of a portion of one embodiment of a block of memory cells.

FIG. 4C depicts a cross sectional view of a portion of one embodiment of a block of memory cells.

FIG. 4D depicts a cross sectional view of a portion of one embodiment of a block of memory cells.

FIG. 4E is a cross sectional view of one embodiment of a vertical column of memory cells.

FIG. 4F is a schematic of a plurality of NAND strings in multiple regions of a same block.

FIG. 5A is a flow chart describing one embodiment of a process for training a model.

FIG. 5B is a flow chart describing one embodiment of a process for using a model with an inference engine.

FIG. 5C depicts vector-matrix multiplication.

FIG. 6 is a perspective view of a portion of one embodiment of a monolithic three dimensional NAND memory structure.

FIGS. 7A-B and 8 provide mathematical details of performing vector-matrix multiplication on the structure of FIG. 6.

FIG. 9 depicts current distributions.

FIGS. 10A-C show examples of different threshold voltage distributions and corresponding cell currents.

FIGS. 11A-D illustrate an example of storing a weight in a group of two memory cells.

FIGS. 12A-D show examples of storing weights in groups of memory cells that include different numbers of memory cells.

FIG. 13 shows an example of physical locations in a memory structure of groups of memory cells, each group storing a weight.

FIG. 14 shows another example of physical locations in a memory structure of groups of memory cells, each group storing a weight.

FIG. 15 shows an example of a method that includes performing vector-matrix operation.

### DETAILED DESCRIPTION

In some memory systems, memory cells are programmed to data states corresponding to threshold voltage distributions or memory cell current distributions. In some cases, memory cells may be programmed to store weights, which may be used to perform in-memory vector-matrix multiplication or other operations for ML or AI applications. Each memory cell may be configured to be programmable to more than two data states (e.g., three or more data states). In order to enable high precision calculation, a higher number of data states may be used. The number of such states may be limited, which may limit precision when performing calculations including vector-matrix multiplication operations.

Aspects of the present technology include using a nonvolatile storage apparatus for performing in-memory vector-matrix multiplication with each weight stored by a group of two or more memory cells. Using two or more memory cells may provide improved storage of weights compared with using one memory cell per weight.

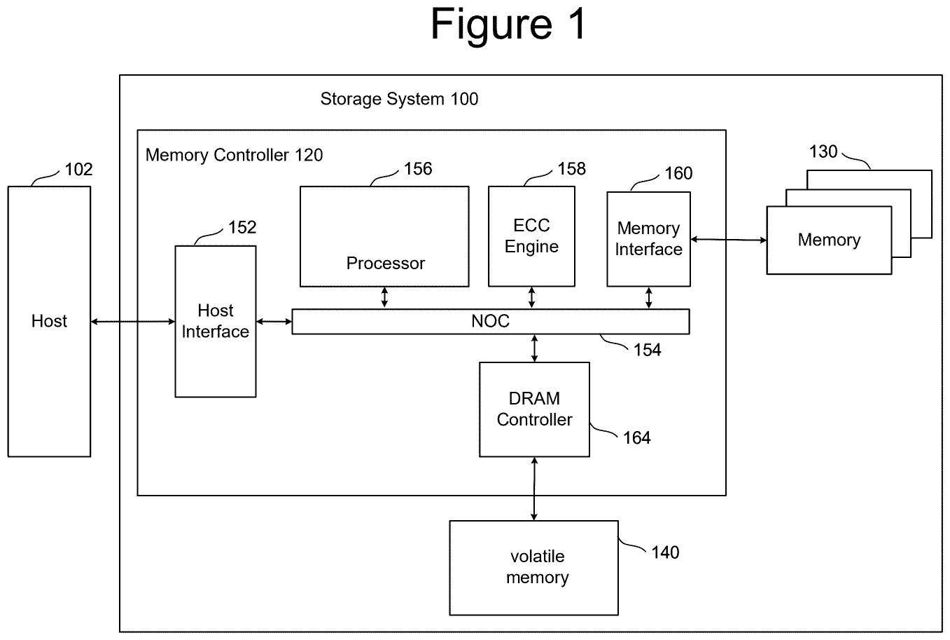

FIG. 1 is a block diagram of one embodiment of a storage system 100 that implements the proposed technology described herein. In one embodiment, storage system 100 is a solid state drive (“SSD”). Storage system 100 can also be a memory card, USB drive or other type of storage system. The proposed technology is not limited to any one type of memory system. Storage system 100 is connected to host 102, which can be a computer, server, electronic device (e.g., smart phone, tablet or other mobile device), appliance, or another apparatus that uses memory and has data processing capabilities. In some embodiments, host 102 is separate from, but connected to, storage system 100. In other embodiments, storage system 100 is embedded within host 102.

The components of storage system 100 depicted in FIG. 1 are electrical circuits. Storage system 100 includes a memory controller 120 connected to nonvolatile memory 130 and local high speed volatile memory 140 (e.g., DRAM). Local high speed volatile memory 140 is used by memory controller 120 to perform certain functions. For example, local high speed volatile memory 140 stores logical to physical address translation tables (“L2P tables”).

Memory controller 120 comprises a host interface 152 that is connected to and in communication with host 102. In one embodiment, host interface 152 implements a NVM Express (NVMe) over PCI Express (PCIe). Other interfaces can also be used, such as SCSI, SATA, etc. Host interface 152 is also connected to a network-on-chip (NOC) 154. A NOC is a communication subsystem on an integrated circuit. NOC's can span synchronous and asynchronous clock domains or use unclocked asynchronous logic. NOC technology applies networking theory and methods to on-chip communications and brings notable improvements over conventional bus and crossbar interconnections. NOC improves the scalability of systems on a chip (SoC) and the power efficiency of complex SoCs compared to other designs. The wires and the links of the NOC are shared by many signals. A high level of parallelism is achieved because all links in the NOC can operate simultaneously on different data packets. Therefore, as the complexity of integrated subsystems keep growing, a NOC provides enhanced performance (such as throughput) and scalability in comparison with previous communication architectures (e.g., dedicated point-to-point signal wires, shared buses, or segmented buses with bridges). In other embodiments, NOC 154 can be replaced by a bus. Connected to and in communication with NOC 154 is processor 156, ECC engine 158, memory interface 160, and DRAM controller 164. DRAM controller 164 is used to operate and communicate with local high speed volatile memory 140 (e.g., DRAM). In other embodiments, local high speed volatile memory 140 can be SRAM or another type of volatile memory.

ECC engine 158 performs error correction services. For example, ECC engine 158 performs data encoding and decoding, as per the implemented ECC technique. In one embodiment, ECC engine 158 is an electrical circuit programmed by software. For example, ECC engine 158 can be a processor that can be programmed. In other embodiments, ECC engine 158 is a custom and dedicated hardware circuit without any software. In another embodiment, the function of ECC engine 158 is implemented by processor 156.

Processor 156 performs the various controller memory operations, such as programming, erasing, reading, and memory management processes. In one embodiment, processor 156 is programmed by firmware. In other embodiments, processor 156 is a custom and dedicated hardware circuit without any software. Processor 156 also implements a translation module, as a software/firmware process or as a dedicated hardware circuit. In many systems, the nonvolatile memory is addressed internally to the storage system using physical addresses associated with the one or more memory die. However, the host system will use logical addresses to address the various memory locations. This enables the host to assign data to consecutive logical addresses, while the storage system is free to store the data as it wishes among the locations of the one or more memory die. To implement this system, memory controller 120 (e.g., the translation module) performs address translation between the logical addresses used by the host and the physical addresses used by the memory dies. One example implementation is to maintain tables (i.e., the L2P tables mentioned above) that identify the current translation between logical addresses and physical addresses. An entry in the L2P table may include an identification of a logical address and corresponding physical address. Although logical address to physical address tables (or L2P tables) include the word “tables” they need not literally be tables. Rather, the logical address to physical address tables (or L2P tables) can be any type of data structure. In some examples, the memory space of a storage system is so large that the local memory 140 cannot hold all of the L2P tables. In such a case, the entire set of L2P tables are stored in a nonvolatile memory 130 and a subset of the L2P tables are cached (L2P cache) in the local high speed volatile memory 140.

Memory interface 160 communicates with nonvolatile memory 130. In one embodiment, memory interface provides a Toggle Mode interface. Other interfaces can also be used. In some example implementations, memory interface 160 (or another portion of controller 120) implements a scheduler and buffer for transmitting data to and receiving data from one or more memory die.

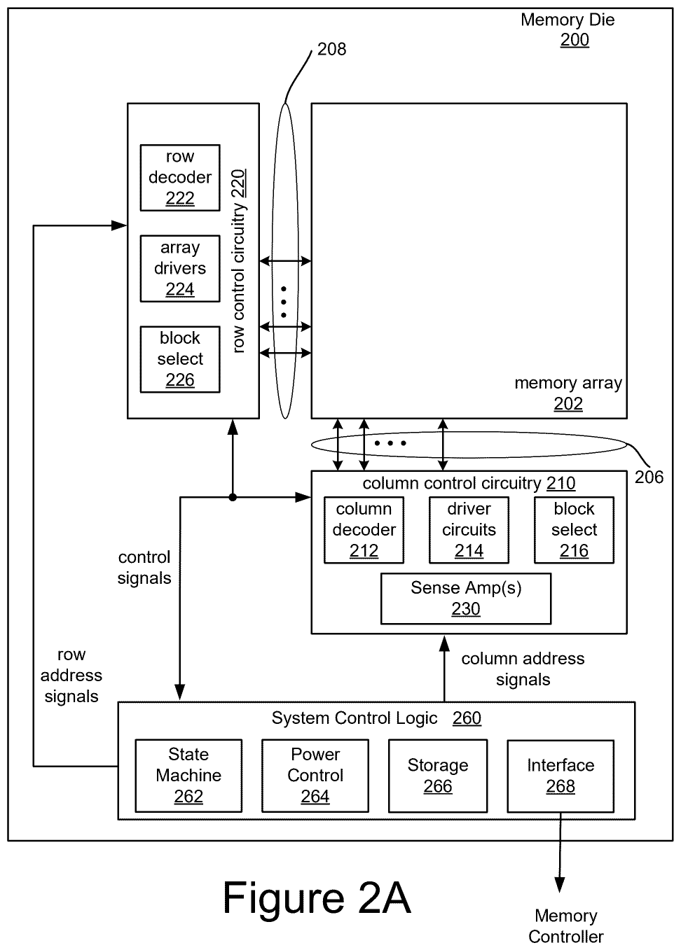

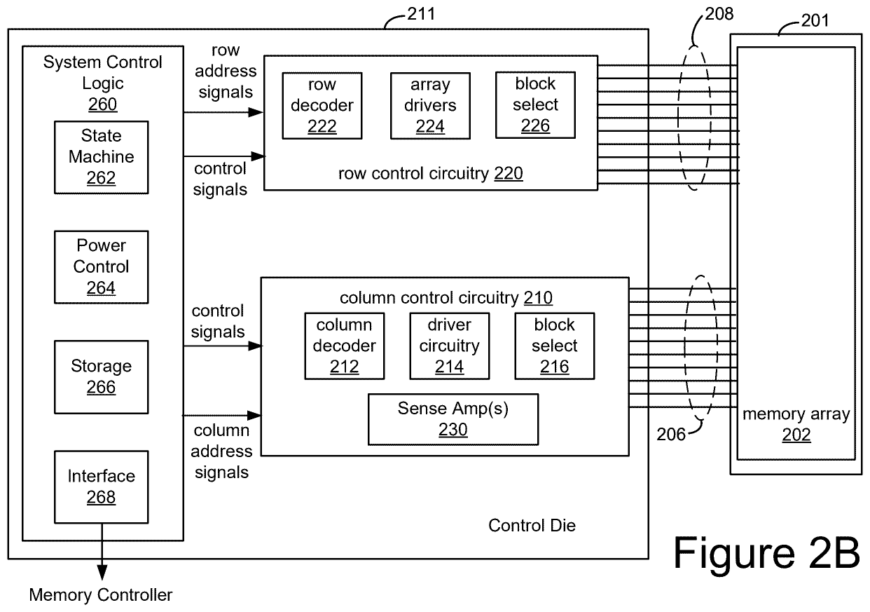

In one embodiment, nonvolatile memory 130 comprises one or more memory die. FIG. 2A is a functional block diagram of one embodiment of a memory die 200 that comprises nonvolatile memory 130. Each of the one or more memory die of nonvolatile memory 130 can be implemented as memory die 200 of FIG. 2A. The components depicted in FIG. 2A are electrical circuits. Memory die 200 includes a memory array 202 that can comprise nonvolatile memory cells, as described in more detail below. The array terminal lines of memory array 202 include the various layer(s) of word lines organized as rows, and the various layer(s) of bit lines organized as columns. However, other orientations can also be implemented. Memory die 200 includes row control circuitry 220, whose outputs 208 are connected to respective word lines of the memory array 202. Row control circuitry 220 receives a group of M row address signals and one or more various control signals from System Control Logic 260, and typically may include such circuits as row decoders 222, array terminal drivers 224, and block select circuitry 226 for both reading and writing (programming) operations. Row control circuitry 220 may also include read/write circuitry. Memory die 200 also includes column control circuitry 210 including sense amplifier(s) 230 whose input/outputs 206 are connected to respective bit lines of the memory array 202. Although only single block is shown for array 202, a memory die can include multiple arrays that can be individually accessed. Column control circuitry 210 receives a group of N column address signals and one or more various control signals from System Control Logic 260, and typically may include such circuits as column decoders 212, array terminal receivers or driver circuits 214, block select circuitry 216, as well as read/write circuitry, and I/O multiplexers.

System control logic 260 receives data and commands from memory controller 120 and provides output data and status to the host. In some embodiments, the system control logic 260 (which comprises one or more electrical circuits) include state machine 262 that provides die-level control of memory operations. In one embodiment, the state machine 262 is programmable by software. In other embodiments, the state machine 262 does not use software and is completely implemented in hardware (e.g., electrical circuits). In another embodiment, the state machine 262 is replaced by a micro-controller or microprocessor, either on or off the memory chip. System control logic 260 can also include a power control module 264 that controls the power and voltages supplied to the rows and columns of the memory structure 202 during memory operations and may include charge pumps and regulator circuit for creating regulating voltages. System control logic 260 includes storage 366 (e.g., RAM, registers, latches, etc.), which may be used to store parameters for operating the memory array 202.

Commands and data are transferred between memory controller 120 and memory die 200 via memory controller interface 268 (also referred to as a “communication interface”). Memory controller interface 268 is an electrical interface for communicating with memory controller 120. Examples of memory controller interface 268 include a Toggle Mode Interface and an Open NAND Flash Interface (ONFI). Other I/O interfaces can also be used.

In some embodiments, all the elements of memory die 200, including the system control logic 260, can be formed as part of a single die. In other embodiments, some or all of the system control logic 260 can be formed on a different die.

In one embodiment, memory structure 202 comprises a memory array of nonvolatile memory cells in which multiple memory levels are formed above a single substrate, such as a wafer. The memory structure may comprise any type of nonvolatile memory that are monolithically formed in one or more physical levels of memory cells having an active area disposed above a silicon (or other type of) substrate. In one example, the nonvolatile memory cells are connected in series to form vertical NAND strings with charge-trapping layers (e.g., to form a three dimensional NAND memory structure).

In another embodiment, memory structure 202 comprises a two-dimensional memory array of nonvolatile memory cells. In one example, the nonvolatile memory cells are NAND flash memory cells utilizing floating gates. Other types of memory cells (e.g., NOR-type flash memory) can also be used.

The exact type of memory array architecture or memory cell included in memory structure 202 is not limited to the examples above. Many different types of memory array architectures or memory technologies can be used to form memory structure 202. No particular nonvolatile memory technology is required for purposes of the new claimed embodiments proposed herein. Other examples of suitable technologies for memory cells of the memory structure 202 include ReRAM memories (resistive random access memories), magnetoresistive memory (e.g., MRAM, Spin Transfer Torque MRAM, Spin Orbit Torque MRAM), FeRAM, phase change memory (e.g., PCM), and the like. Examples of suitable technologies for memory cell architectures of the memory structure 202 include two dimensional arrays, three dimensional arrays, cross-point arrays, stacked two dimensional arrays, vertical bit line arrays, and the like.

One example of a ReRAM cross-point memory includes reversible resistance-switching elements arranged in cross-point arrays accessed by X lines and Y lines (e.g., word lines and bit lines). In another embodiment, the memory cells may include conductive bridge memory elements. A conductive bridge memory element may also be referred to as a programmable metallization cell. A conductive bridge memory element may be used as a state change element based on the physical relocation of ions within a solid electrolyte. In some cases, a conductive bridge memory element may include two solid metal electrodes, one relatively inert (e.g., tungsten) and the other electrochemically active (e.g., silver or copper), with a thin film of the solid electrolyte between the two electrodes. As temperature increases, the mobility of the ions also increases causing the programming threshold for the conductive bridge memory cell to decrease. Thus, the conductive bridge memory element may have a wide range of programming thresholds over temperature.

Another example is magnetoresistive random access memory (MRAM) that stores data by magnetic storage elements. The elements are formed from two ferromagnetic layers, each of which can hold a magnetization, separated by a thin insulating layer. One of the two layers is a permanent magnet set to a particular polarity; the other layer's magnetization can be changed to match that of an external field to store memory. A memory device is built from a grid of such memory cells. In one embodiment for programming, each memory cell lies between a pair of write lines arranged at right angles to each other, parallel to the cell, one above and one below the cell. When current is passed through them, an induced magnetic field is created. MRAM based memory embodiments will be discussed in more detail below.

Phase change memory (PCM) exploits the unique behavior of chalcogenide glass. One embodiment uses a GeTe-Sb2Te3 super lattice to achieve non-thermal phase changes by simply changing the co-ordination state of the Germanium atoms with a laser pulse (or light pulse from another source). Therefore, the doses of programming are laser pulses. The memory cells can be inhibited by blocking the memory cells from receiving the light. In other PCM embodiments, the memory cells are programmed by current pulses. Note that the use of “pulse” in this document does not require a square pulse but includes a (continuous or non-continuous) vibration or burst of sound, current, voltage light, or another wave. These memory elements within the individual selectable memory cells, or bits, may include a further series element that is a selector, such as an ovonic threshold switch or metal insulator substrate.

A person of ordinary skill in the art will recognize that the technology described herein is not limited to a single specific memory structure, memory construction or material composition, but covers many relevant memory structures within the spirit and scope of the technology as described herein and as understood by one of ordinary skill in the art.

The elements of FIG. 2A can be grouped into two parts: (1) memory structure 202 and (2) peripheral circuitry, which includes all of the other components depicted in FIG. 2A. An important characteristic of a memory circuit is its capacity, which can be increased by increasing the area of the memory die of storage system 100 that is given over to the memory structure 202; however, this reduces the area of the memory die available for the peripheral circuitry. This can place quite severe restrictions on these elements of the peripheral circuitry. For example, the need to fit sense amplifier circuits within the available area can be a significant restriction on sense amplifier design architectures. With respect to the system control logic 260, reduced availability of area can limit the available functionalities that can be implemented on-chip. Consequently, a basic trade-off in the design of a memory die for the storage system 100 is the amount of area to devote to the memory structure 202 and the amount of area to devote to the peripheral circuitry.

Another area in which the memory structure 202 and the peripheral circuitry are often at odds is in the processing involved in forming these regions, since these regions often involve differing processing technologies and the trade-off in having differing technologies on a single die. For example, when the memory structure 202 is NAND flash, this is an NMOS structure, while the peripheral circuitry is often CMOS based. For example, elements such sense amplifier circuits, charge pumps, logic elements in a state machine, and other peripheral circuitry in system control logic 260 often employ PMOS devices. Processing operations for manufacturing a CMOS die will differ in many aspects from the processing operations optimized for an NMOS flash NAND memory or other memory cell technologies.

To improve upon these limitations, embodiments described below can separate the elements of FIG. 2A onto separately formed dies that are then bonded together. More specifically, the memory structure 202 can be formed on one die (referred to as the memory die) and some or all of the peripheral circuitry elements, including one or more control circuits, can be formed on a separate die (referred to as the control die). For example, a memory die can be formed of just the memory elements, such as the array of memory cells of flash NAND memory, MRAM memory, PCM memory, ReRAM memory, or other memory type. Some or all of the peripheral circuitry, even including elements such as decoders and sense amplifiers, can then be moved on to a separate control die. This allows each of the memory die to be optimized individually according to its technology. For example, a NAND memory die can be optimized for an NMOS based memory array structure, without worrying about the CMOS elements that have now been moved onto a control die that can be optimized for CMOS processing. This allows more space for the peripheral elements, which can now incorporate additional capabilities that could not be readily incorporated were they restricted to the margins of the same die holding the memory cell array. The two die can then be bonded together in a bonded multi-die memory circuit, with the array on the one die connected to the periphery elements on the other die. Although the following will focus on a bonded memory circuit of one memory die and one control die, other embodiments can use more die, such as two memory die and one control die, for example.

FIG. 2B shows an alternative arrangement to that of FIG. 2A which may be implemented using wafer-to-wafer bonding to provide a bonded die pair. FIG. 2B depicts a functional block diagram of one embodiment of an integrated memory assembly 207. One or more integrated memory assemblies 207 may be used to implement the nonvolatile memory 130 of storage system 100. The integrated memory assembly 207 includes two types of semiconductor die (or more succinctly, “die”). Memory die 201 includes memory structure 202. Memory structure 202 includes nonvolatile memory cells. Control die 211 includes control circuitry 260, 210, and 220 (as described above). In some embodiments, control die 211 is configured to connect to the memory structure 202 in the memory die 201. In some embodiments, the memory die 201 and the control die 211 are bonded together.

FIG. 2B shows an example of the peripheral circuitry, including control circuits, formed in a peripheral circuit or control die 211 coupled to memory structure 202 formed in memory die 201. Common components are labelled similarly to FIG. 2A. System control logic 260, row control circuitry 220, and column control circuitry 210 are located in control die 211. In some embodiments, all or a portion of the column control circuitry 210 and all or a portion of the row control circuitry 220 are located on the memory die 201. In some embodiments, some of the circuitry in the system control logic 260 is located on the on the memory die 201.

System control logic 260, row control circuitry 220, and column control circuitry 210 may be formed by a common process (e.g., CMOS process), so that adding elements and functionalities, such as ECC, more typically found on a memory controller 120 may require few or no additional process steps (i.e., the same process steps used to fabricate controller 120 may also be used to fabricate system control logic 260, row control circuitry 220, and column control circuitry 210). Thus, while moving such circuits from a die such as memory die 201 may reduce the number of steps needed to fabricate such a die, adding such circuits to a die such as control die 211 may not require many additional process steps. The control die 211 could also be referred to as a CMOS die, due to the use of CMOS technology to implement some or all of control circuitry 260, 210, 220.

FIG. 2B shows column control circuitry 210 including sense amplifier(s) 230 on the control die 211 coupled to memory structure 202 on the memory die 201 through electrical paths 206. For example, electrical paths 206 may provide electrical connection between column decoder 212, driver circuitry 214, and block select 216 and bit lines of memory structure 202. Electrical paths may extend from column control circuitry 210 in control die 211 through pads on control die 211 that are bonded to corresponding pads of the memory die 201, which are connected to bit lines of memory structure 202. Each bit line of memory structure 202 may have a corresponding electrical path in electrical paths 206, including a pair of bond pads, which connects to column control circuitry 210. Similarly, row control circuitry 220, including row decoder 222, array drivers 224, and block select 226 are coupled to memory structure 202 through electrical paths 208. Each of electrical path 208 may correspond to a word line, dummy word line, or select gate line. Additional electrical paths may also be provided between control die 211 and memory die 201.

For purposes of this document, the phrases “a control circuit” or “one or more control circuits” can include any one of or any combination of memory controller 120, state machine 262, all or a portion of system control logic 260, all or a portion of row control circuitry 220, all or a portion of column control circuitry 210, a microcontroller, a microprocessor, and/or other similar functioned circuits. The control circuit can include hardware only or a combination of hardware and software (including firmware). For example, a controller programmed by firmware to perform the functions described herein is one example of a control circuit. A control circuit can include a processor, FGA, ASIC, integrated circuit, or other type of circuit.

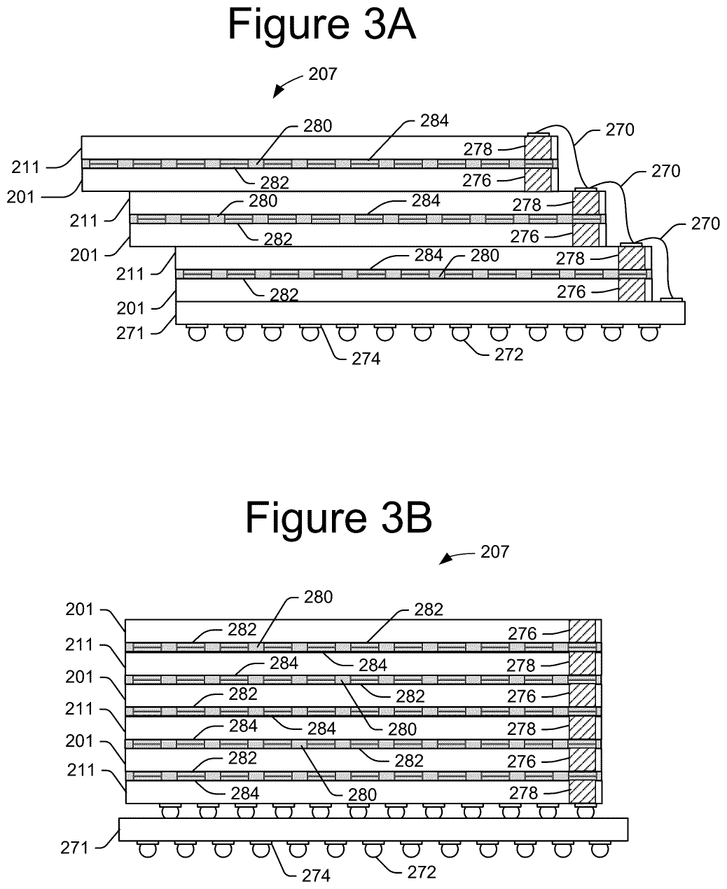

In some embodiments, there is more than one control die 211 and more than one memory die 201 in an integrated memory assembly 207. In some embodiments, the integrated memory assembly 207 includes a stack of multiple control die 211 and multiple memory die 201. FIG. 3A depicts a side view of an embodiment of an integrated memory assembly 207 stacked on a substrate 271 (e.g., a stack comprising control dies 211 and memory dies 201). The integrated memory assembly 207 has three control dies 211 and three memory dies 201. In some embodiments, there are more than three memory dies 201 and more than three control die 211.

Each control die 211 is affixed (e.g., bonded) to at least one of the memory dies 201. Some of the bond pads 282/284 are depicted. There may be many more bond pads. A space between two dies 201, 211 that are bonded together is filled with a solid layer 280, which may be formed from epoxy or other resin or polymer. This solid layer 280 protects the electrical connections between the dies 201, 211, and further secures the dies together. Various materials may be used as solid layer 280, but in embodiments, it may be Hysol epoxy resin from Henkel Corp., having offices in California, USA.

The integrated memory assembly 207 may for example be stacked with a stepped offset, leaving the bond pads at each level uncovered and accessible from above. Wire bonds 270 connected to the bond pads connect the control die 211 to the substrate 271. A number of such wire bonds may be formed across the width of each control die 211 (i.e., into the page of FIG. 3A).

A memory die through silicon via (TSV) 276 may be used to route signals through a memory die 201. A control die through silicon via (TSV) 278 may be used to route signals through a control die 211. The TSVs 276, 278 may be formed before, during or after formation of the integrated circuits in the semiconductor dies 201, 211. The TSVs may be formed by etching holes through the wafers. The holes may then be lined with a barrier against metal diffusion. The barrier layer may in turn be lined with a seed layer, and the seed layer may be plated with an electrical conductor such as copper, although other suitable materials such as aluminum, tin, nickel, gold, doped polysilicon, and alloys or combinations thereof may be used.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package. The solder balls 272 may form a part of the interface between integrated memory assembly 207 and memory controller 120.

FIG. 3B depicts a side view of another embodiment of an integrated memory assembly 207 stacked on a substrate 271. The integrated memory assembly 207 of FIG. 3B has three control die 211 and three memory die 201. In some embodiments, there are many more than three memory dies 201 and many more than three control dies 211. In this example, each control die 211 is bonded to at least one memory die 201. Optionally, a control die 211 may be bonded to two or more memory die 201.

Some of the bond pads 282, 284 are depicted. There may be many more bond pads. A space between two dies 201, 211 that are bonded together is filled with a solid layer 280, which may be formed from epoxy or other resin or polymer. In contrast to the example in FIG. 3A, the integrated memory assembly 207 in FIG. 3B does not have a stepped offset. A memory die through silicon via (TSV) 276 may be used to route signals through a memory die 201. A control die through silicon via (TSV) 278 may be used to route signals through a control die 211.

Solder balls 272 may optionally be affixed to contact pads 274 on a lower surface of substrate 271. The solder balls 272 may be used to couple the integrated memory assembly 207 electrically and mechanically to a host device such as a printed circuit board. Solder balls 272 may be omitted where the integrated memory assembly 207 is to be used as an LGA package.

As has been briefly discussed above, the control die 211 and the memory die 201 may be bonded together. Bond pads on each memory die 201, 211 may be used to bond the two dies together. In some embodiments, the bond pads are bonded directly to each other, without solder or other added material, in a so-called Cu-to-Cu bonding process. In a Cu-to-Cu bonding process, the bond pads are controlled to be highly planar and formed in a highly controlled environment largely devoid of ambient particulates that might otherwise settle on a bond pad and prevent a close bond. Under such properly controlled conditions, the bond pads are aligned and pressed against each other to form a mutual bond based on surface tension. Such bonds may be formed at room temperature, though heat may also be applied. In embodiments using Cu-to-Cu bonding, the bond pads may be about 5 μm square and spaced from each other with a pitch of 5 μm to 5 μm. While this process is referred to herein as Cu-to-Cu bonding, this term may also apply even where the bond pads are formed of materials other than Cu.

When the area of bond pads is small, it may be difficult to bond the semiconductor dies together. The size of, and pitch between, bond pads may be further reduced by providing a film layer on the surfaces of the semiconductor dies including the bond pads. The film layer is provided around the bond pads. When the dies are brought together, the bond pads may bond to each other, and the film layers on the respective dies may bond to each other. Such a bonding technique may be referred to as hybrid bonding. In embodiments using hybrid bonding, the bond pads may be about 5 μm square and spaced from each other with a pitch of 1 μm to 5 μm. Bonding techniques may be used providing bond pads with even smaller (or greater) sizes and pitches.

Some embodiments may include a film on surface of the dies 201, 211. Where no such film is initially provided, a space between the dies may be under filled with an epoxy or other resin or polymer. The under-fill material may be applied as a liquid which then hardens into a solid layer. This under-fill step protects the electrical connections between the dies 201, 211, and further secures the dies together. Various materials may be used as under-fill material, but in embodiments, it may be Hysol epoxy resin from Henkel Corp., having offices in California, USA.

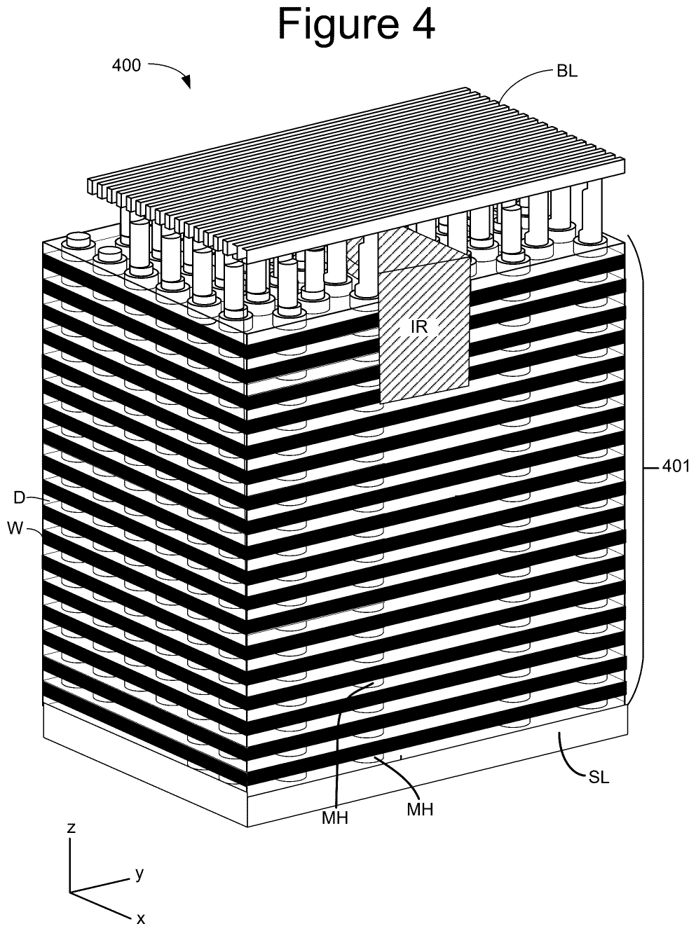

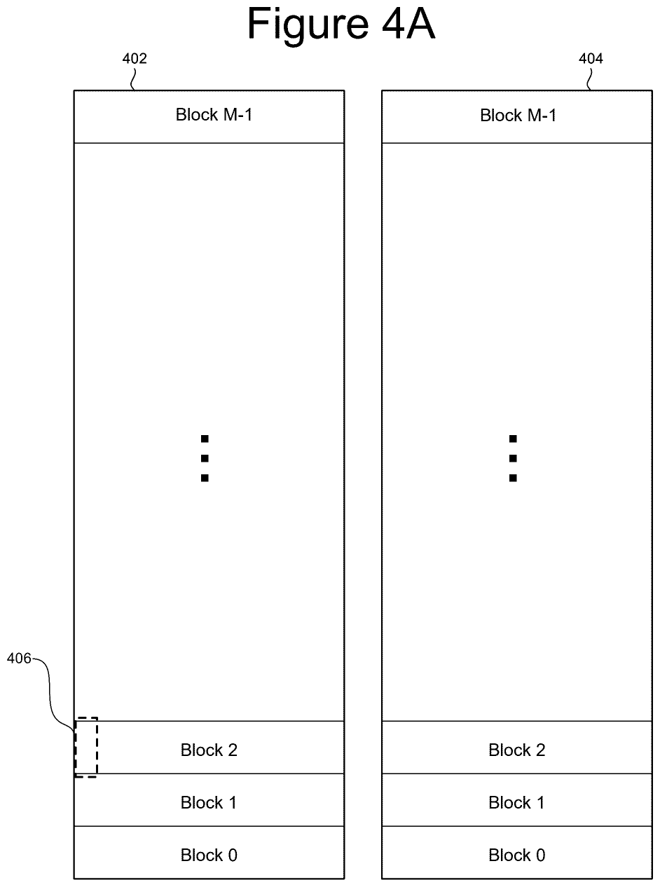

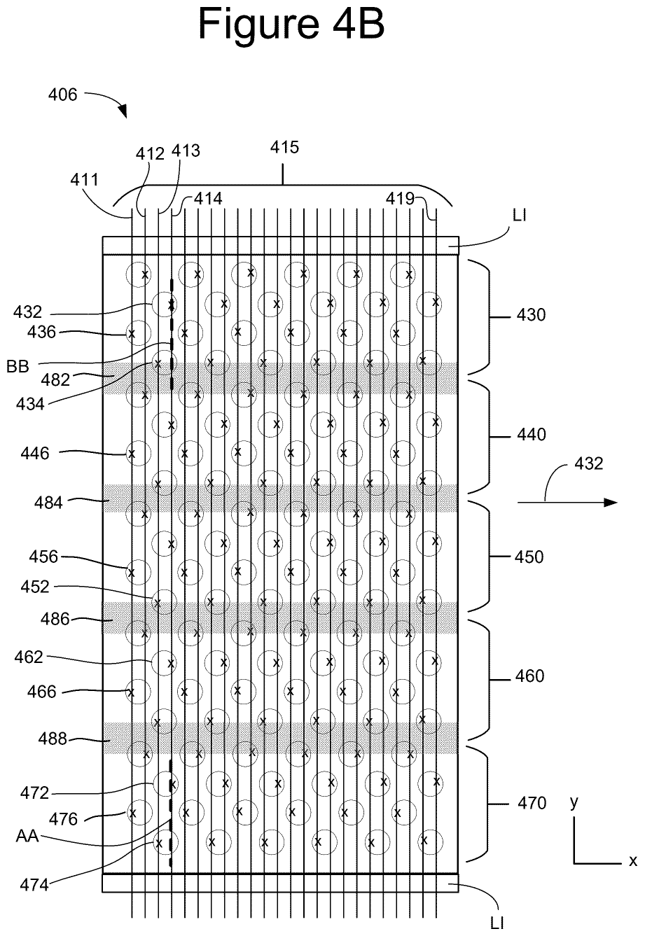

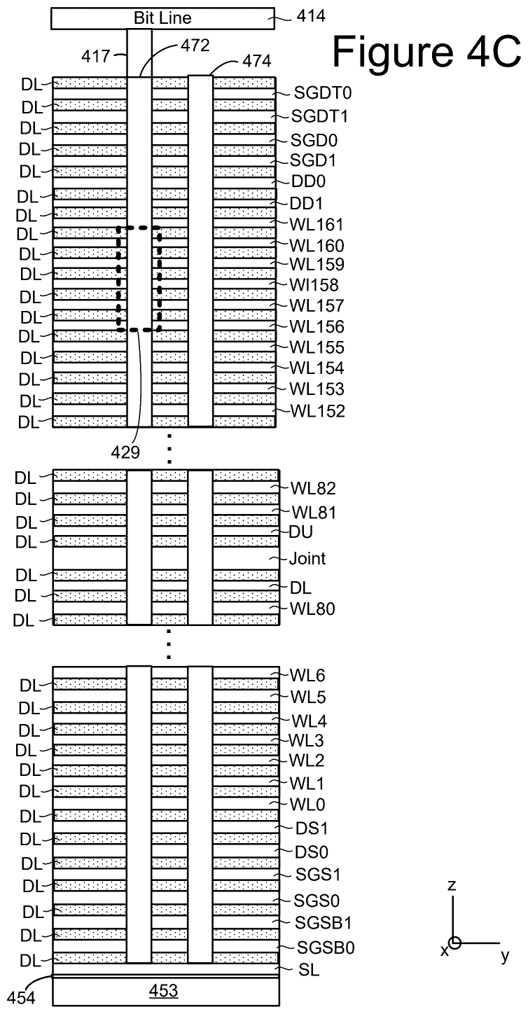

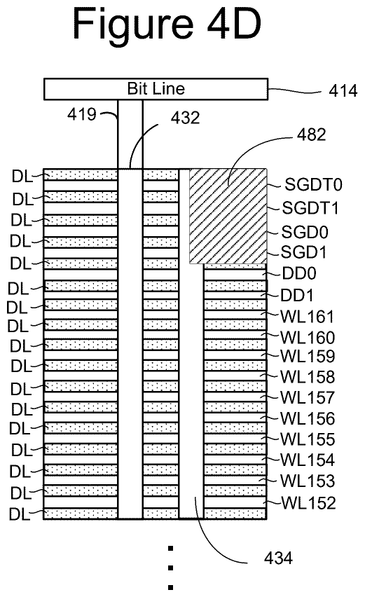

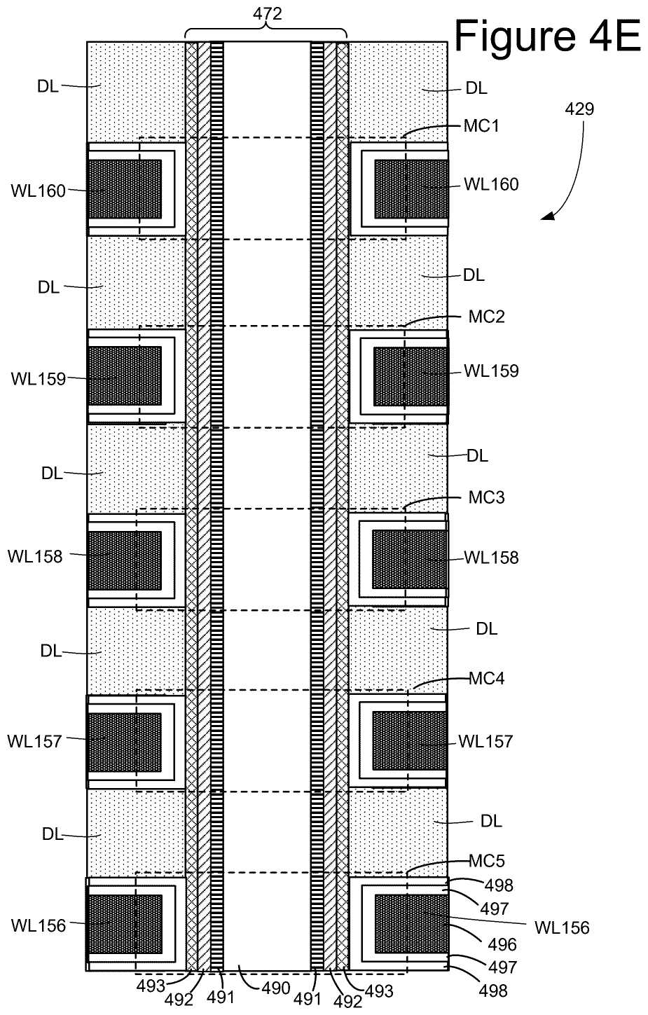

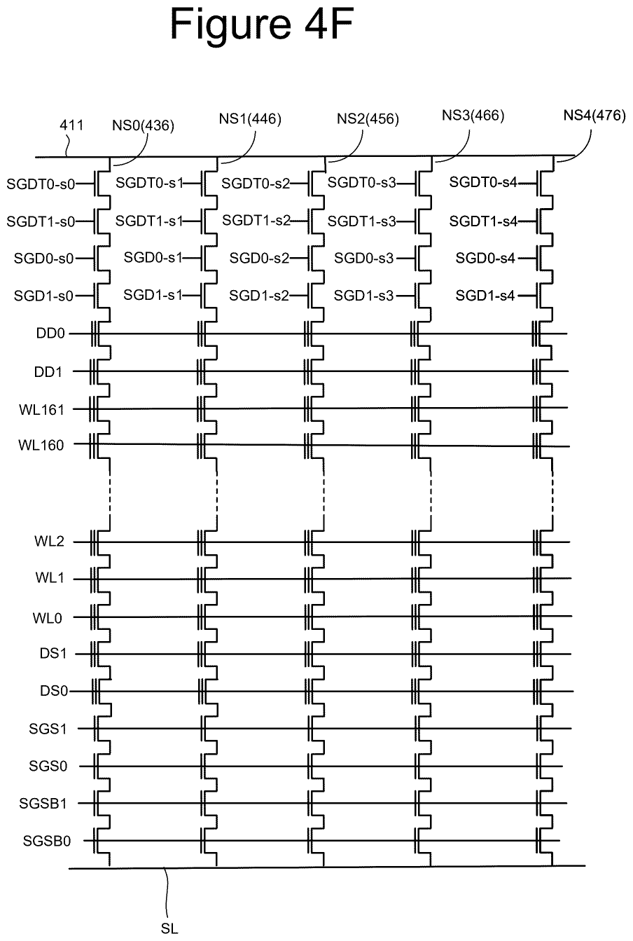

FIG. 4 is a perspective view of a portion of one example embodiment of a monolithic three dimensional memory array/structure that can comprise memory structure 202, which includes a plurality nonvolatile memory cells arranged as vertical NAND strings. For example, FIG. 4 shows a portion 400 of one block of memory. The structure depicted includes a set of bit lines BL positioned above a stack 401 of alternating dielectric layers and conductive layers. For example purposes, one of the dielectric layers is marked as D and one of the conductive layers (also called word line layers) is marked as W. The number of alternating dielectric layers and conductive layers can vary based on specific implementation requirements. As will be explained below, in one embodiment the alternating dielectric layers and conductive layers are divided into four or five (or a different number of) regions by isolation regions IR. FIG. 4 shows one isolation region IR separating two regions. Below the alternating dielectric layers and word line layers is a source line layer SL. Memory holes are formed in the stack of alternating dielectric layers and conductive layers. For example, one of the memory holes is marked as MH. Note that in FIG. 4, the dielectric layers are depicted as see-through so that the reader can see the memory holes positioned in the stack of alternating dielectric layers and conductive layers. In one embodiment, NAND strings are formed by filling the memory hole with materials including a charge-trapping material to create a vertical column of memory cells. Each memory cell can store one or more bits of data. Thus, the nonvolatile memory cells are arranged in memory holes. More details of the three dimensional monolithic memory array that comprises memory structure 202 is provided below.

FIG. 4A is a block diagram explaining one example organization of memory structure 202, which is divided into two planes 402 and 404. Each plane is then divided into M blocks. In one example, each plane has about 2000 blocks. However, different numbers of blocks and planes can also be used. In one embodiment, a block of memory cells is a unit of erase. That is, all memory cells of a block are erased together. In other embodiments, blocks can be divided into sub-blocks and the sub-blocks can be the unit of erase. Memory cells can also be grouped into blocks for other reasons, such as to organize the memory structure to enable the signaling and selection circuits. In some embodiments, a block represents a groups of connected memory cells as the memory cells of a block share a common set of word lines. For example, the word lines for a block are all connected to all of the vertical NAND strings for that block. Although FIG. 4A shows two planes 402/404, more or less than two planes can be implemented. In some embodiments, memory structure 202 includes eight planes.

FIGS. 4B-4F depict an example three dimensional (“3D”) NAND structure that corresponds to the structure of FIG. 4 and can be used to implement memory structure 202 of FIGS. 2A and 2B. FIG. 4B is a block diagram depicting a top view of a portion 406 of Block 2 of plane 402. As can be seen from FIG. 4B, the block depicted in FIG. 4B extends in the direction of 432. In one embodiment, the memory array has many layers; however, FIG. 4B only shows the top layer.

FIG. 4B depicts a plurality of circles that represent the memory holes, which are also referred to as vertical columns. Each of the memory holes/vertical columns include multiple select transistors (also referred to as a select gate or selection gate) and multiple memory cells. In one embodiment, each memory hole/vertical column implements a NAND string. For example, FIG. 4B labels a subset of the memory holes/vertical columns/NAND strings 432, 436, 446. 456, 462, 466, 472, 474 and 476.

FIG. 4B also depicts a set of bit lines 415, including bit lines 411, 412, 413, 414, . . . 419. FIG. 4B shows twenty four bit lines because only a portion of the block is depicted. It is contemplated that more than twenty four bit lines connected to memory holes/vertical columns of the block. Each of the circles representing memory holes/vertical columns has an “x” to indicate its connection to one bit line. For example, bit line 411 is connected to memory holes/vertical columns 436, 446, 456, 466 and 476.

The block depicted in FIG. 4B includes a set of isolation regions 482, 484, 486 and 488, which are formed of SiO₂; however, other dielectric materials can also be used. Isolation regions 482, 484, 486 and 488 serve to divide the top layers of the block into five regions; for example, the top layer depicted in FIG. 4B is divided into regions 430, 440, 450, 460 and 470. In one embodiment, the isolation regions only divide the layers used to implement select gates so that NAND strings in different regions can be independently selected. In one example implementation, a bit line connects to one memory hole/vertical column/NAND string in each of regions 430, 440, 450, 460 and 470. In that implementation, each block has twenty four rows of active columns and each bit line connects to five rows in each block. In one embodiment, all of the five memory holes/vertical columns/NAND strings connected to a common bit line are connected to the same set of word lines; therefore, the system uses the drain side select lines to choose one (or another subset) of the five to be subjected to a memory operation (program, verify, read, and/or erase).

FIG. 4B also shows Line Interconnects LI, which are metal connections to the source line SL from above the memory array. Line Interconnects LI are positioned adjacent regions 430 and 470.

Although FIG. 4B shows each region 430, 440, 450, 460 and 470 having four rows of memory holes/vertical columns, five regions and twenty four rows of memory holes/vertical columns in a block, those exact numbers are an example implementation. Other embodiments may include more or less regions per block, more or less rows of memory holes/vertical columns per region and more or less rows of vertical columns per block. FIG. 4B also shows the memory holes/vertical columns being staggered. In other embodiments, different patterns of staggering can be used. In some embodiments, the memory holes/vertical columns are not staggered.

FIG. 4C depicts a portion of one embodiment of a three dimensional memory structure 202 showing a cross-sectional view along line AA of FIG. 4B. This cross sectional view cuts through memory holes/vertical columns (NAND strings) 472 and 474 of region 470 (see FIG. 4B). The structure of FIG. 4C includes two drain side select layers SGD0 and SGD; two source side select layers SGS0 and SGS1; two drain side GIDL generation transistor layers SGDT0 and SGDT1; two source side GIDL generation transistor layers SGSB0 and SGSB1; two drain side dummy word line layers DD0 and DD1; two source side dummy word line layers DS0 and DS1; dummy word line layers DU and DL; one hundred and sixty two word line layers WL0-WL161 for connecting to data memory cells, and dielectric layers DL. Other embodiments can implement more or less than the numbers described above for FIG. 4C. In one embodiment, SGD0 and SGD1 are connected together; and SGS0 and SGS1 are connected together. In other embodiments, more or fewer SGDs (greater or lesser than two) are connected together, and more or fewer SGSs (greater or lesser than two) connected together.

Memory holes/Vertical columns 472 and 474 are depicted protruding through the drain side select layers, source side select layers, dummy word line layers, GIDL generation transistor layers and word line layers. In one embodiment, each memory hole/vertical column comprises a vertical NAND string. Below the memory holes/vertical columns and the layers listed below is substrate 453, an insulating film 454 on the substrate, and source line SL. The NAND string of memory hole/vertical column 472 has a source end at a bottom of the stack and a drain end at a top of the stack. As in agreement with FIG. 4B, FIG. 4C show vertical memory hole/column 472 connected to bit line 414 via connector 417.

For ease of reference, drain side select layers; source side select layers, dummy word line layers, GIDL generation transistor layers and data word line layers collectively are referred to as the conductive layers. In one embodiment, the conductive layers are made from a combination of TiN and Tungsten. In other embodiments, other materials can be used to form the conductive layers, such as doped polysilicon, metal such as Tungsten, metal silicide, such as nickel silicide, tungsten silicide, aluminum silicide or the combination thereof. In some embodiments, different conductive layers can be formed from different materials. Between conductive layers are dielectric layers DL. In one embodiment, the dielectric layers are made from SiO₂. In other embodiments, other dielectric materials can be used to form the dielectric layers.

The nonvolatile memory cells are formed along memory holes/vertical columns which extend through alternating conductive and dielectric layers in the stack. In one embodiment, the memory cells are arranged in NAND strings. The word line layers WL0-W161 connect to memory cells (also called data memory cells). Dummy word line layers connect to dummy memory cells. A dummy memory cell does not store and is not eligible to store host data (data provided from the host, such as data from a user of the host), while a data memory cell is eligible to store host data. In some embodiments, data memory cells and dummy memory cells may have a same structure. Drain side select layers SGD0 and SGD1 are used to electrically connect and disconnect NAND strings from bit lines. Source side select layers SGS0 and SGS1 are used to electrically connect and disconnect NAND strings from the source line SL.

FIG. 4C shows that the memory array is implemented as a two tier architecture, with the tiers separated by a Joint area. In one embodiment it is expensive and/or challenging to etch so many word line layers intermixed with dielectric layers. To ease this burden, one embodiment includes laying down a first stack of word line layers (e.g., WL0-WL80) alternating with dielectric layers, laying down the Joint area, and laying down a second stack of word line layers (e.g., WL81-WL161) alternating with dielectric layers. The Joint area are positioned between the first stack and the second stack. In one embodiment, the Joint areas are made from the same materials as the word line layers. In other embodiments, there can no Joint area or there can be multiple Joint areas.

FIG. 4D depicts a portion of one embodiment of a three dimensional memory structure 202 showing a cross-sectional view along line BB of FIG. 4B. This cross sectional view cuts through memory holes/vertical columns (NAND strings) 432 and 434 of region 430 (see FIG. 4B). FIG. 4D shows the same alternating conductive and dielectric layers as FIG. 4C. FIG. 4D also shows isolation region 482. Isolation regions 482, 484, 486 and 488) occupy space that would have been used for a portion of the memory holes/vertical columns/NAND stings. For example, isolation region 482 occupies space that would have been used for a portion of memory hole/vertical column 434. More specifically, a portion (e.g., half the diameter) of vertical column 434 has been removed in layers SGDT0, SGDT1, SGD0, and SGD1 to accommodate isolation region 482. Thus, while most of the vertical column 434 is cylindrical (with a circular cross section), the portion of vertical column 434 in layers SGDT0, SGDT1, SGD0, and SGD1 has a semi-circular cross section. In one embodiment, after the stack of alternating conductive and dielectric layers is formed, the stack is etched to create space for the isolation region and that space is then filled in with SiO₂. This structure allows for separate control of SGDT0, SGDT1, SGD0, and SGD1 for regions 430, 440, 450, 460, and 470.

FIG. 4E depicts a cross sectional view of region 429 of FIG. 4C that includes a portion of memory hole/vertical column 472. In one embodiment, the memory holes/vertical columns are round; however, in other embodiments other shapes can be used. In one embodiment, memory hole/vertical column 472 includes an inner core 490 that is made of a dielectric, such as SiO₂. Other materials can also be used. Surrounding inner core 490 is polysilicon channel 491. Materials other than polysilicon can also be used. Note that it is the channel 491 that connects to the bit line and the source line. Surrounding channel 491 is a tunneling dielectric 492. In one embodiment, tunneling dielectric 492 has an ONO structure. Surrounding tunneling dielectric 492 is charge trapping layer 493, such as (for example) Silicon Nitride. Other memory materials and structures can also be used. The technology described herein is not limited to any particular material or structure.

FIG. 4E depicts dielectric layers DL as well as word line layers WL160, WL159, WL158, WL157, and WL156. Each of the word line layers includes a word line region 496 surrounded by an aluminum oxide layer 497, which is surrounded by a blocking oxide layer 498. In other embodiments, the blocking oxide layer can be a vertical layer parallel and adjacent to charge trapping layer 493. The physical interaction of the word line layers with the vertical column forms the memory cells. Thus, a memory cell, in one embodiment, comprises channel 491, tunneling dielectric 492, charge trapping layer 493, blocking oxide layer 498, aluminum oxide layer 497 and word line region 496. For example, word line layer WL160 and a portion of memory hole/vertical column 472 comprise a memory cell MC1. Word line layer WL159 and a portion of memory hole/vertical column 472 comprise a memory cell MC2. Word line layer WL158 and a portion of memory hole/vertical column 472 comprise a memory cell MC3. Word line layer WL157 and a portion of memory hole/vertical column 472 comprise a memory cell MC4. Word line layer WL156 and a portion of memory hole/vertical column 472 comprise a memory cell MC5. In other architectures, a memory cell may have a different structure; however, the memory cell would still be the storage unit.

When a memory cell is programmed, electrons are stored in a portion of the charge trapping layer 493 which is associated with (e.g. in) the memory cell. These electrons are drawn into the charge trapping layer 493 from the channel 491, through the tunneling dielectric 492, in response to an appropriate voltage on word line region 496. The threshold voltage (Vth) of a memory cell is increased in proportion to the amount of stored charge. In one embodiment, the programming is achieved through Fowler-Nordheim tunneling of the electrons into the charge trapping layer. During an erase operation, the electrons return to the channel or holes are injected into the charge trapping layer to recombine with electrons. In one embodiment, erasing is achieved using hole injection into the charge trapping layer via a physical mechanism such as GIDL.

FIG. 4F is a schematic diagram of a portion of the three dimensional memory structure 202 depicted in in FIGS. 4-4E. FIG. 4F shows physical data word lines WL0-WL161 running across the entire block. The structure of FIG. 4F corresponds to a portion 406 in Block 2 of FIG. 4A, including bit line 411. Within the block, in one embodiment, each bit line is connected to five NAND strings, one in each region of regions 430, 440, 450, 460, 470. Thus, FIG. 4F shows bit line 411 connected to NAND string NS0 (which corresponds to memory hole/vertical column 436 of region 430), NAND string NS1 (which corresponds to memory hole/vertical column 446 of region 440), NAND string NS2 (which corresponds to vertical column 456 of region 450), NAND string NS3 (which corresponds to memory hole/vertical column 466 of region 460), and NAND string NS4 (which corresponds to memory hole/vertical column 476 of region 470).

Drain side select line/layer SGD0 is separated by isolation regions 482, 484, 486 and 488 to form SGD0-s0, SGD0-s1, SGD0-s2, SGD0-s3 and SGD0-s4 in order to separately connect to and independently control regions 430, 440, 450, 460, 470. Similarly, drain side select line/layer SGD1 is separated by isolation regions 482, 484, 486 and 488 to form SGD1-s0, SGD1-s1, SGD1-s2, SGD1-s3 and SGD1-s4 in order to separately connect to and independently control regions 430, 440, 450, 460, 470; drain side GIDL generation transistor control line/layer SGDT0 is separated by isolation regions 482, 484, 486 and 488 to form SGDT0-s0, SGDT0-s1, SGDT0-s2, SGDT0-s3 and SGDT0-s4 in order to separately connect to and independently control regions 430, 440, 450, 460, 470; drain side GIDL generation transistor control line/layer SGDT1 is separated by isolation regions 482, 484, 486 and 488 to form SGDT1-s0, SGDT1-s1, SGDT1-s2, SGDT1-s3 and SGDT1-s4 in order to separately connect to and independently control regions 430, 440, 450, 460, 470.

FIG. 4F only shows NAND strings connected to bit line 411. However, a full schematic of the block would show every bit line and five vertical NAND strings (that are in separate regions) connected to each bit line.

Although the example memories of FIGS. 4-4F are three dimensional memory structure that includes vertical NAND strings with charge-trapping material, other (2D and 3D) memory structures can also be used with the technology described herein. The memory systems discussed above can be erased, programmed and read.

The memory structures described above can be used with artificial intelligence and machine learning applications.

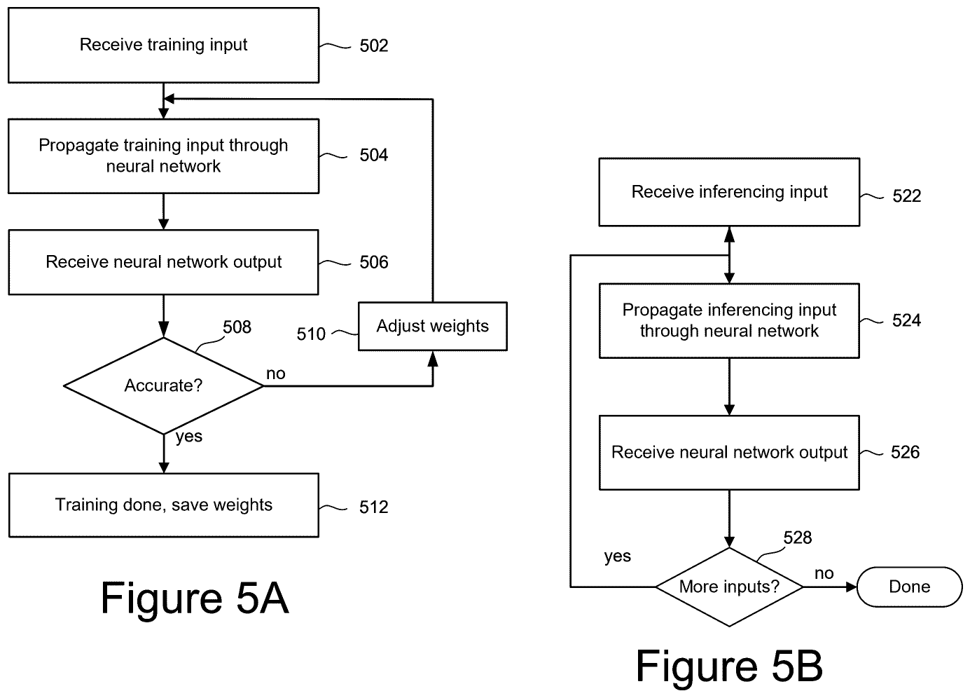

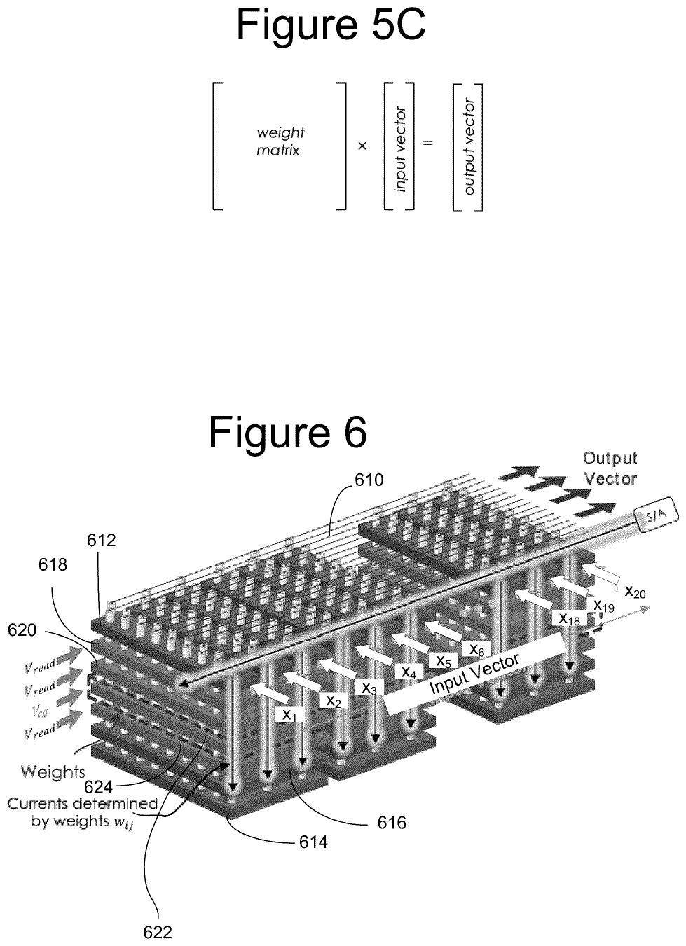

Artificial neural networks are finding increasing usage in artificial intelligence and machine learning applications. In an artificial neural network, a set of inputs is propagated through one or more intermediate, or hidden, layers to generate an output. The layers connecting the input to the output are connected by one or more sets of weights that are generated in a training or learning phase by determining a set of a mathematical manipulations to turn the input into the output, moving through the layers calculating the probability of each output. Once the weights are established, they can be used in the inference phase to determine the output from a set of inputs. The set of weights can be referred to as a model. The determining of the weights is referred to as training the model. FIG. 5A is a flow chart describing one embodiment of a process for training a model. The use of the weights with real data is referred to as the inference phrase and is performed by using the neural network as an inference engine. FIG. 5B is a flow chart describing one embodiment of a process for using a trained model with the neural network as an inference engine.

An artificial neural network is “trained” by supplying inputs and then checking and correcting the outputs. For example, a neural network that is trained to recognize dog breeds will process a set of images and calculate the probability that the dog in an image is a certain breed. During training, a user can review the results and return the proposed label. Each mathematical manipulation when determining an answer is considered a layer, and complex neural networks have many layers. Due to the depth provided by a large number of intermediate or hidden layers, neural networks can model complex non-linear relationships as they are trained.

FIG. 5A is a flowchart describing one embodiment of a process for training a model to generate a set of weights. The training process is often performed in the cloud, allowing additional or more powerful processing engines to be accessed. At step 502, the input, such as a set of images, is received. At step 504 the input is propagated through the layers of the neural network using the set of weights. The neural network's output is then received at the output in step 506. In one example of a neural network designed to recognize dog breeds, the input would be the image data of a number of dogs, and the one or more intermediate layers use the current weight values to calculate the probability that the dog in an image is a certain breed, with the proposed dog breed label returned at step 506. A user can then review the results at step 508 to select which probabilities the neural network should return and decide whether the current set of weights supply a sufficiently accurate labelling and, if so, the training is complete (step 512). If the result is not sufficiently accurate, the neural network adjusts the weights at step 510 based on the probabilities the user selected, followed by looping back to step 504 to run the input data again with the adjusted weights. Once the neural network's set of weights have been determined, they can be used to “inference,” which is the process of using the determined weights to generate an output result from data input into the neural network. Once the weights are determined at step 512, they can then be stored in nonvolatile memory for later use.

FIG. 5B is a flowchart describing a process for the inference phase to predict a result from the input data. At step 522, the input is received, such as the image of a dog in the example used above. At step 524, the input data is then propagated through the neural network's one or more layers using the weights established at the end of the training process at step 512. After propagating the input through the layers, the output is then provided at step 526. If there are more inputs to process (step 528), then the method loops back to step 522; otherwise, the inferencing is completed.

A basic operation used in artificial intelligence and machine learning applications (e.g., used by the neural network as an inference engine) is vector-matrix multiplication (VMM), which comprises multiplying an input vector by a weight matrix, resulting in an output vector, as depicted in FIG. 5C. VMM is used at each layer of a neural network.

Although neural networks can provide highly accurate results, they are extremely computationally intensive, require the storage of an enormous amount of data (e.g., the weights) and the data transfers involved in reading the weights from memory into the processors can be time intensive. For example, an artificial intelligence/machine learning application may need to store 175 billion weights. Prior systems store weights in DRAM, which is very expensive. When needed, the weights are transferred to a GPU, which wastes time. To overcome both of these issues, it is proposed to store the weights in nonvolatile memory, such as the NAND memory discussed above with respect to FIGS. 4-4F. Such NAND memory is significantly less expensive than DRAM. Furthermore, the nonvolatile memory can be configured to perform the vector-matrix multiplication in-memory using the weights stored in the nonvolatile memory as part of the inference phase, thereby, removing the need to transfer the weights to an external processor that is implementing the inference engine. Thus, using the nonvolatile memory to store the weights and perform the vector-matrix multiplication increases performance (e.g., not wasting time on large data transfers) and reduces cost (NAND is cheaper than DRAM).

FIG. 6 is a perspective view of a portion of one embodiment of the monolithic three dimensional memory structure of FIGS. 4-4F configured to perform vector-matrix multiplication. The memory structure includes many memory holes/vertical columns implementing NAND strings. The NAND strings comprise nonvolatile memory cells and select gates, as discussed above. The NAND strings are grouped into a plurality of blocks (see e.g., FIG. 4A). The portion of the memory depicted in FIG. 6 includes bit lines 610 connected to the top of the NAND strings, a drain side select line 612 (e.g., any of SGD0 or SGD1) connected to drain side select gates of the NAND strings, source side select lines 614 and 616 (e.g., SGS1 and SGS0) connected to source side select gates of the NAND strings and data word lines 618, 620, 622 and 624 (e.g., any of WL0-WL161) connected to the memory cells of the NAND strings. Each of the bit lines 610 are connected to NAND strings in every block of the plurality of blocks (e.g., connected to Block 0-Block M-1 of FIG. 4A). In one embodiment, each bit line is connected to one NAND string in every region (e.g., of regions 430, 440, 450, 460 and 470 of FIG. 4B) of every block of a plane. FIG. 6 is simplified to only show a subset of the data word lines, bit lines and select lines in order to make the drawing easier to read; however, the memory of FIG. 6 will include all of the structures depicted in FIGS. 4B-4E (including all of the word lines and select lines describe above). Each of the memory cells stores weight information (which can be a weight or information from which the weight can be derived). The weights are stored in the memory cells as part of step 512 of FIG. 5A.

To perform vector-matrix multiplication in and by the nonvolatile memory, using the weights stored in the memory cells of the nonvolatile memory, the control circuit applies read enable voltages to the word lines (e.g., applies Vcg to the selected word line 622 connected to the memory cells selected for sensing because they are storing the weights needed for the VMM and applies Vread [an overdrive or pass voltage ˜5-8v also revered to as Vpass] to word lines 618/620/624 that are unselected); applies an input vector to one or more select lines (e.g., select line 612) while applying the read enable voltages to the word lines, and senses an output vector from the bit lines 610 using the senses amplifiers (S/A) 230. The voltage Vcg is one example of a reference voltage, discussed below. The sensed output vector is a set of output currents sensed on bit lines 610. In one embodiment, each bit line is connected to one NAND string in every region of every block of a plane; therefore, the bit line can potentially receive current concurrently from multiple NAND strings (i.e. one NAND string in each region of each block of a plane). The current received at the bit line from the multiple NAND strings is added together such that the sense amplifier senses the sum of the current from the multiple NAND strings.

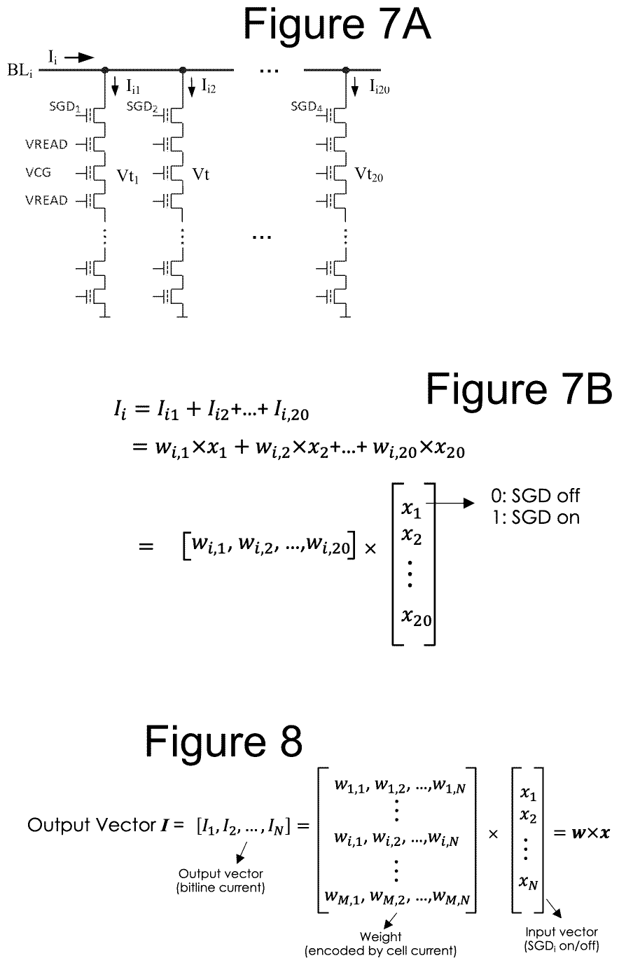

FIG. 7A shows an example of adding current from 20 NAND strings that are connected to a common bit line, Blᵢ, so that current through bit line Blᵢ (current Iᵢ) is the sum of currents I₁ to I₂₀ of the individual NAND strings. This is further detailed by the math of FIG. 7B which shows the total current Blᵢ is the sum of the current Iᵢ₁ from a first NAND string, the current Iᵢ₂ from a second NAND string, . . . the current Iᵢ₂₀ from a twentieth NAND string, etc. FIG. 7B shows math for twenty NAND strings but in other embodiments, a bit line can be connected to and concurrently receiving current from hundreds or thousands of NAND strings. In one embodiment, there are 16K bit lines. The current from any given NAND string is the product of the weight stored in the selected memory cell in the NAND string and the magnitude at the relevant position of the input vector. For example, the current Iᵢ₁ from the first NAND string is Iᵢ₁=w_{i,1}(x₁), where w_{i,1} is the weight stored in the selected memory cell (connected to word line 622) on the first NAND string and x₁ is the magnitude of the signal on the SGD line 612 connected to the first NAND string. In one embodiment, the SGD line is either logic 1 (on) or logic 0 (off). FIG. 8 indicates that the output vector I includes each of the current magnitudes from the multiple bit lines 610, and represents the product the matrix of weights (w_{x,y}) and the input vector (ₓ₁, x₂, . . . x_{N}).

In one embodiment, the weights are stored in the memory cells as analog values representing current that will flow though the memory cells (e.g., between the source and drain) when applying a reference voltage to the gate (encoding weight information as memory cell current in the memory cells). In one example implementation, the memory cells can be programmed to store any current magnitude (e.g., an analog value or an integer).

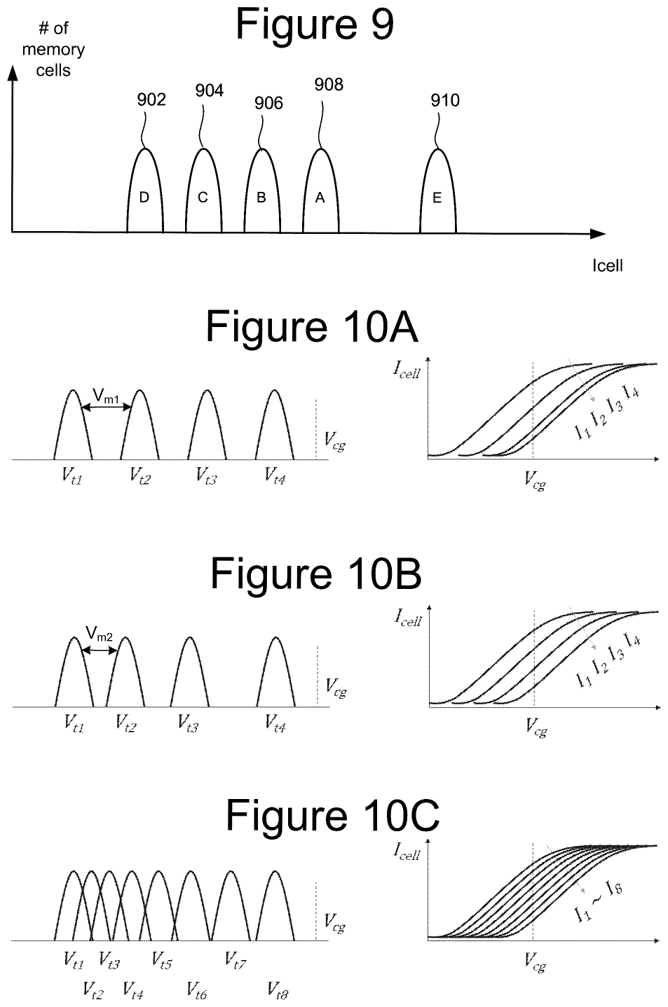

In another embodiment, the nonvolatile memory cells are configured to be programmed into a set of data states defined by current distributions when applying a common voltage (e.g., Vcg) to the nonvolatile memory cells. For example, FIG. 9 depicts current distributions 902, 904, 906, 908 and 910. Current distribution 910 represents erased memory cells (the erased state or unprogrammed state). From the erased state, memory cells can be programmed to current distribution 908 (representing data state A), current distribution 906 (representing data state B), current distribution 904 (representing data state C), and current distribution 902 (representing data state D). All of the memory cells in data state A are storing the same weight. That is, when applying a reference voltage (e.g., Vcg) to the gate of the memory cells, a current will flow between the source and the drain that has a magnitude in current distribution 908. All of the memory cells in data state B are storing the same weight such that when applying a reference voltage to the gate of the memory cells, a current will flow between the source and the drain that has a magnitude in current distribution 906. All of the memory cells in data state C are storing the same weight such that when applying a reference voltage to the gate of the memory cells, a current will flow between the source and the drain that has a magnitude in current distribution 904. All of the memory cells in data state D are storing the same weight such that when applying a reference voltage to the gate of the memory cells, a current will flow between the source and the drain that has a magnitude in current distribution 902. In one example embodiment, current distribution 908 is centered at 80 nA, current distribution 906 is centered at 60 nA, current distribution 904 is centered at 40 nA, and current distribution 902 is centered at 20 nA. In the embodiment of FIG. 9, memory cells can store four different magnitudes of weights (four data states). In other embodiments, memory cells can store more than four different magnitudes of weights by implementing more current distributions.

While FIG. 9 shows data states A-D that are evenly spaced along the horizontal (cell current, Icell) axis, in some examples current and/or voltage ranges associated with different data states may be unequally spaced apart.

FIGS. 10A-C illustrate examples of memory cell threshold voltage distributions and corresponding cell currents. FIG. 10A shows an example of threshold voltage distributions Vt1 to Vt4, which correspond to data states (e.g., each cell is configured to be programmable to four data states). Voltage distributions Vt1 to Vt4 are evenly spaced with a voltage margin, Vm1, that is sufficient to ensure a low error rate. Corresponding cell currents, Icell, for the four data states are shown on the left (I₁ to I₄). It can be seen that current distributions when Vcg is applied are not equally spaced, which may increase errors. In contrast, FIG. 10B shows an example where threshold voltage distributions Vt1 to Vt4 are unequally spaced so that corresponding cell currents I₁ to I₄ are evenly spaced apart when Vcg is applied (e.g., as illustrated in FIG. 9). To obtain even spacing of current distributions, voltage margin between at least some of distributions Vt1 to Vt4 may be reduced compared with FIG. 10A. For example, FIG. 10B shows voltage margin Vm2 between Vt1 and Vt2 distributions where Vm2 is less than Vm1. While FIG. 10B shows four distributions that are sufficiently separated (e.g., at least Vm2) to avoid high error rates, such a voltage margin may not always be present. For example, FIG. 10C shows an example of eight threshold voltage distributions Vt1 to Vt8 (left), which are unevenly distributed in order to ensure that distributions of corresponding cell currents, I₁ to I₈ (right), are evenly distributed. Because of the increase in the number of data states and the unequal spacing of threshold voltage distributions, significant overlap between threshold voltage ranges of different data states occurs. In this case, a high number of errors may occur in data stored in memory cells (e.g., weights for vector-matrix multiplication). This may make it difficult to implement weights with higher numbers of data states (e.g., using more than, for example, four data states).

Aspects of the present technology are directed to technical problems associated with storing weights in nonvolatile memory cells (e.g., more than four possible values for an individual weight). Aspects of the present technology provide technical solutions that include storing an individual weight for vector-matrix multiplication in two or more memory cells. Each such cell may operate with a relatively low number of data states (e.g., four) so that sufficient margin is provided to avoid excessive errors while the combined memory cells may represent a weight using a large number of combined data states (e.g., seven or more) to provide high precision.

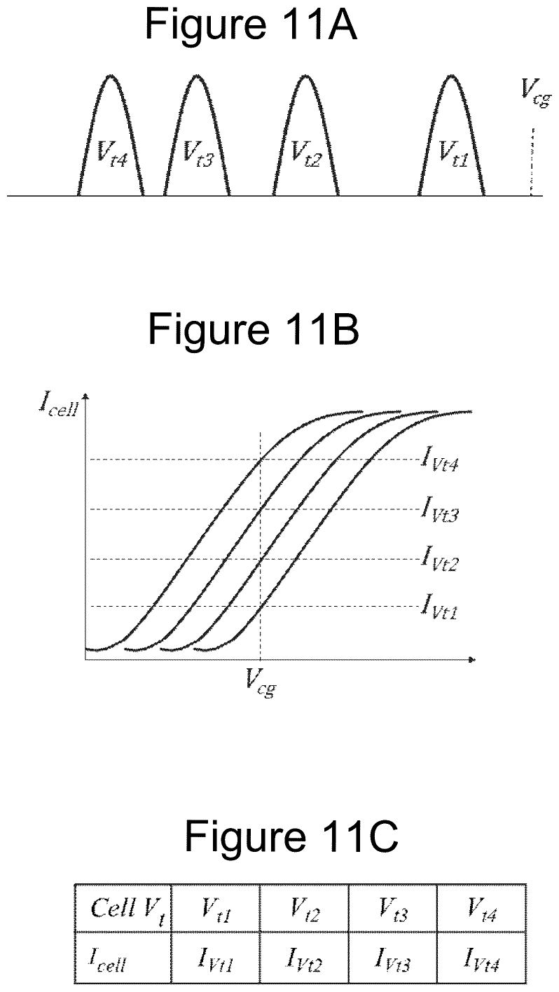

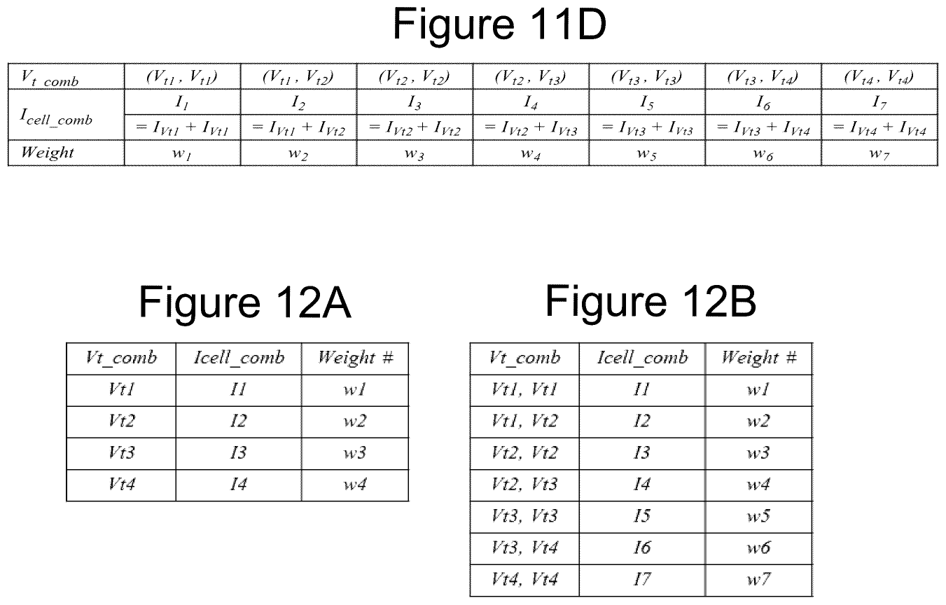

FIGS. 11A-C illustrate an example of a nonvolatile memory cell that is configured to be operated in combination with a second nonvolatile memory cell to form a group of nonvolatile memory cells that together store a weight (e.g., each individual weight may be stored by a combination of two or more nonvolatile memory cells). In this example, the group of nonvolatile memory cells consists of a pair of nonvolatile memory cells (e.g., two and only two memory cells) while in other examples more than two memory cells may be similarly combined. Nonvolatile memory cells of the group may be identically operated and the example of FIGS. 11A-C may be representative of any such nonvolatile memory cell.

FIG. 11A shows four threshold voltage distributions, Vt1 to Vt4, corresponding to four data states, with unequal spacing. FIG. 11B shows cell current (Icell) for the four voltage distributions of FIG. 11A including four I-V curves corresponding to the four data states where the horizontal axis corresponds to voltage applied to a control gate of a memory cell (e.g., voltage applied on a selected word line). Cell current Icell when Vcg is applied is shown for each distribution (Ivt1 to Ivt4). FIG. 11C illustrates the relationship between cell threshold voltage distributions (e.g., FIG. 11A) and corresponding cell current when Vcg is applied (e.g., FIG. 11B). For example, when Vcg is applied to cells in a first data state with threshold voltage Vt1 the cell current is Ivt1, when Vcg is applied to cells in a second data state with threshold voltage Vt2 the cell current is Ivt2, when Vcg is applied to cells in a third data state with threshold voltage Vt3 the cell current is Ivt3 and when Vcg is applied to cells in a fourth data state with threshold voltage Vt4 the cell current is Ivt4.

FIG. 11D illustrates an example of how two memory cells or a pair of memory cells (e.g., first and second memory cells, each as described in FIGS. 11A-C) may be configured and operated so that more kinds of weight (more values) are available, which may provide higher precision computing. The table of FIG. 11D includes a top row that shows various combinations of memory cell threshold voltages with corresponding data states for the two memory cells. The middle row shows corresponding combined current which is the sum of currents through the individual memory cells (cells are connected in parallel). The bottom row shows a weight represented by the combined data states of the two memory cells. For example, a first weight, w1, is represented by threshold voltages Vt1, Vt1, which results in cell current I1=Ivt1+Ivt1. A second weight, w2, is represented by threshold voltages Vt1, Vt2, which results in cell current I2=Ivt1+Ivt2. A third weight, w3, is represented by threshold voltages Vt2, Vt2, which results in cell current I3=Ivt2+Ivt2 and so on. By programming the two memory cells to appropriate data states that result in different combined currents, seven different weights may be stored in a pair of memory cells that each has four data states thus providing more weight values that using a single cell to store each weight. While additional combinations of data states may be possible, some possible combinations may result in the same or similar currents and may not be resolvable so that they are not used in the example shown.

While the example of FIGS. 11A-D refers to memory cells that have four data states, in other examples memory cells may be configured for different numbers of data states (e.g., in some cases more than four data states per memory cell may be possible). Furthermore, the number of memory cells used to store a weight is not limited to two and the present technology may include storing a single weight using data states of a group of memory cells that may include three, four, or more memory cells. The present technology is not limited to any particular number of data states per cell, number of cells per group or mapping of cell data states to weights.

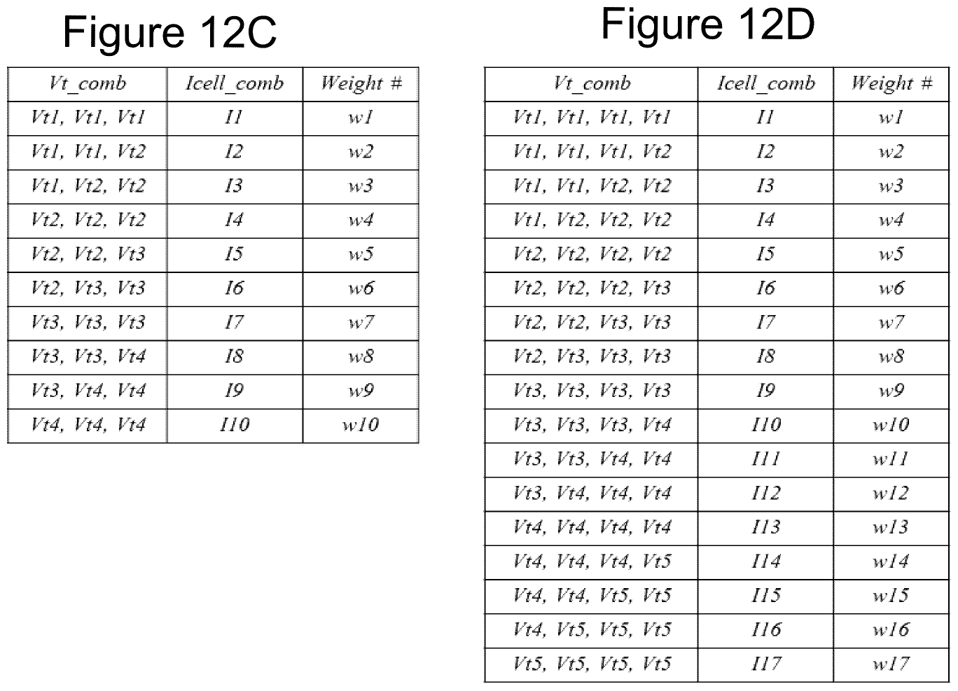

FIGS. 12A-D illustrate examples of storing weights in one, two, three and four memory cells respectively where each memory cell has four data states. For example, FIG. 12A shows an example where a weight is stored in a single memory cell with each data state corresponding to a value of the weight (e.g., four values from w1 to w4). FIG. 12B shows an example where a weight is stored by a group of two memory cells using the mapping previously illustrated in FIG. 11D to map seven possible weight values (w1 to w7) to seven possible combined data states. FIG. 12C illustrates an example where a weight is stored by a group of three memory cells using a mapping that provides ten possible weight values (w1 to w10) and FIG. 12D shows an example where a weight is stored by a group of four memory cells using a mapping that provides seventeen possible weight values (w1 to w17). It can be seen that using increasing numbers of cells to store an individual weight enables more weight values, which may enable improved machine learning (e.g., more accuracy).

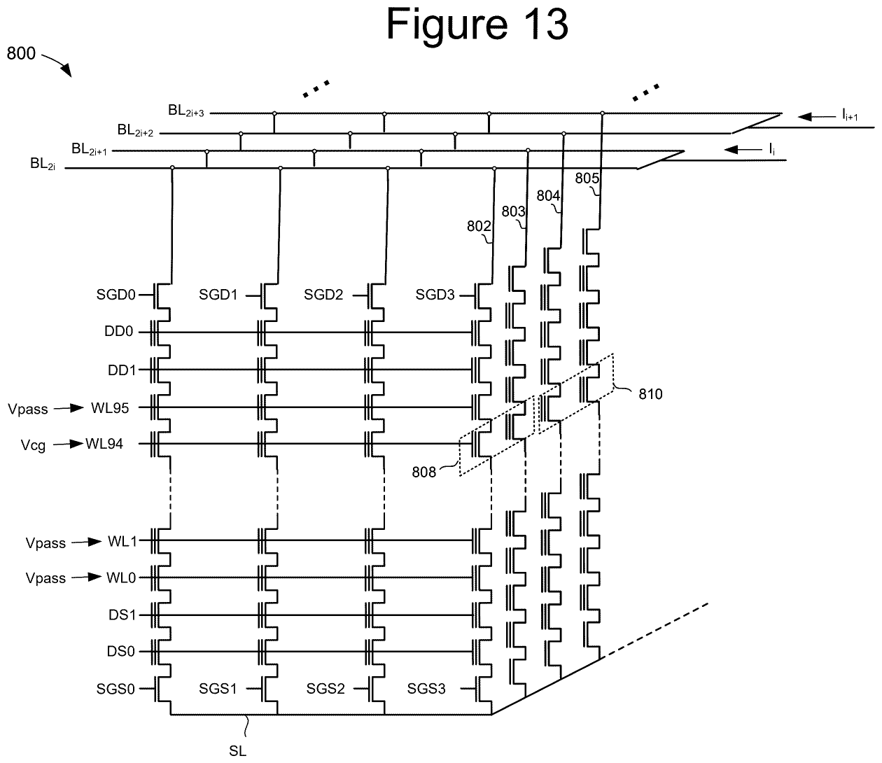

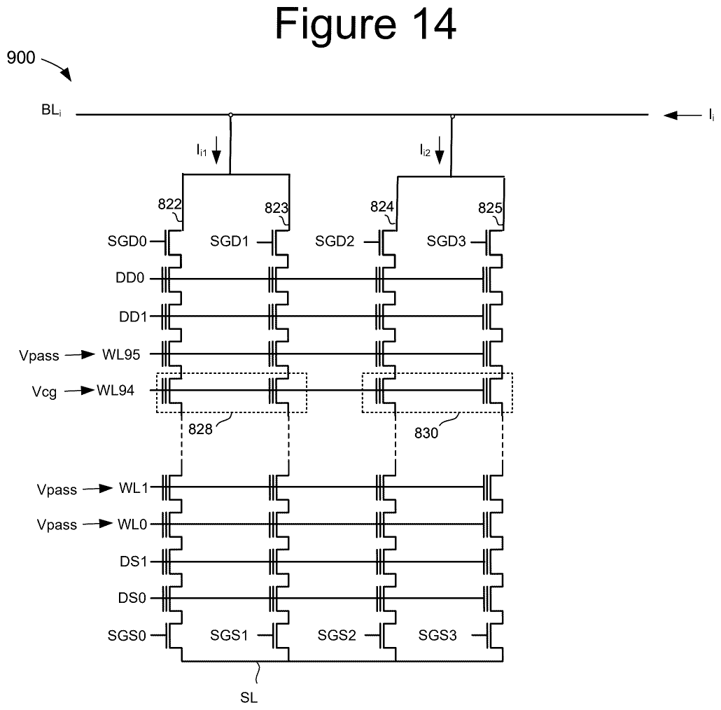

The physical arrangement of memory cells that form a group to collectively store a weight is not limited to a particular arrangement and the two or more memory cells in such a group may be in any suitable arrangement. FIGS. 13 and 14 show two examples of arrangements for groups consisting of two memory cells.

FIG. 13 shows an example of a portion of a nonvolatile memory structure 800 which includes four bit lines (BL₂ᵢ to BL₂ᵢ₊₃) each of which is connected to multiple NAND strings as previously described. The view of FIG. 13 includes four NAND strings 802-805, which are connected to BL₂ᵢ to BL₂ᵢ₊₃ respectively. Neighboring memory cells form groups of two (pairs) with each such pair used to store a weight. For example, cells 808 of WL94 form a group (pair) of cells that may be programmed to data states to collectively represent a weight (e.g., as illustrated in FIG. 11D). When Vcg is applied to WL94 and a pass voltage “Vpass” is applied to non-selected word lines as illustrated, the currents through NAND strings 802 and 803 depends on the respective data states of memory cells 808 and thus on the weight represented by the data states. For example, the current Ii is the sum of the currents through BL2i and BL2i+1 which result from currents through NAND strings 802 and 803. The magnitude of combined current Ii depends on the data states of cells and weight stored in cells 808 (e.g., according to the table of FIG. 11D so that Ii=I1 corresponds to w1, Ii=I2 corresponds to w2, Ii=I3 corresponds to w3 and so on). Output current Ii may be used as part of an output vector (which may include additional currents such as Ii+1 that depend on different weights stored in different memory cells). For example, cells 810 form another group (pair) of memory cells in NAND strings 804-805, which are connected to BL2i+2 and BL2i+3 respectively receive Vcg (e.g., cells 810 are selected). Current through NAND strings 804-805 depends on a weight stored by data states of the two cells, which contributes to current Iᵢ₊₁ through connected bit lines BL₂ᵢ₊₂ and BL₂ᵢ₊₃. Similarly, other weights may be stored in other pairs of memory cells in neighboring NAND strings that are connected to neighboring bit lines. While bit lines BL₂ᵢ₊₂ and BL₂ᵢ₊₃.are shown as physically connected together with Ii+1 flowing through the combined bit lines and BL₂ᵢ and BL₂ᵢ₊₁ are shown as physically connected together with Ii flowing through the combined bit lines, such a physical connection of bit lines is not necessary to obtain a combined current (e.g., currents may be separately sensed and the combined current may be obtained by performing an addition operation on the results of the sensing operations). For example, one or more control circuits may be configured to add current through a first bit line (e.g., BL₂ᵢ) and current through the second bit line (BL₂ᵢ₊₁) to obtain a combined current in a vector-matrix multiplication operation. While two selected pairs of cells 808 and 810 are illustrated in FIG. 13, additional pairs may include additional cells of NAND strings 802-805 and other NAND strings in nonvolatile memory structure 800.

While FIG. 13 shows an example in which a first group of memory cells 808 includes a first memory cell located in a first NAND string connected to a first bit line (e.g., NAND string 802 connected to BL₂ᵢ) and the second memory cell located in a second NAND string connected to a second bit line (e.g., NAND string 803 connected to BL2i+1), in other examples pairs of cells may be formed differently.

FIG. 14 shows an example in which a group of memory cells includes a first memory cell located in a first NAND string connected to a bit line and a second memory cell located in a second NAND string connected to the same bit line. For example, FIG. 14 shows a portion of a memory structure 900, which includes four NAND strings 822 to 825, which are connected to bit line BLi. A group of two memory cells 828 is formed from memory cells of NAND strings 822 and 823 that are connected to WL94. Memory cells 828 are programmed to memory states that represent a weight. For example, a weight may be represented by data states of cells 828 as illustrated by the table of FIG. 11D so that the combined current Ii1 through NAND strings 822 and 823 may have seven possible values corresponding to seven weights w1 to w7. Similarly, a group of two memory cells 830 is formed from memory cells of NAND strings 824 and 825 that are connected to WL94. A weight may be represented by data states as illustrated by the table of FIG. 11D so that the combined current Ii2 through NAND strings 824 and 825 when WL94 is selected (WL94 receives Vcg and unselected word lines receive Vpass) may have seven possible values, w1 to w7 according to the data states of memory cells 830. While NAND strings 822 and 823 are shown as physically connected a distance from BLi to illustrate combined current Ii, no such separate connection is necessary (e.g., NAND strings 824 and 825 may be physically connected on their drains side by BLi without another physical connection). Similarly, NAND strings 824 and 825 (and all other NAND strings connected to BLi) may extend up to BLi without being connected at an intermediate level. The current Ii through BLi may be the sum of Ii1, Ii2 and any other currents through other NAND strings that are selected (e.g., by applying a pass voltage to corresponding select gates).

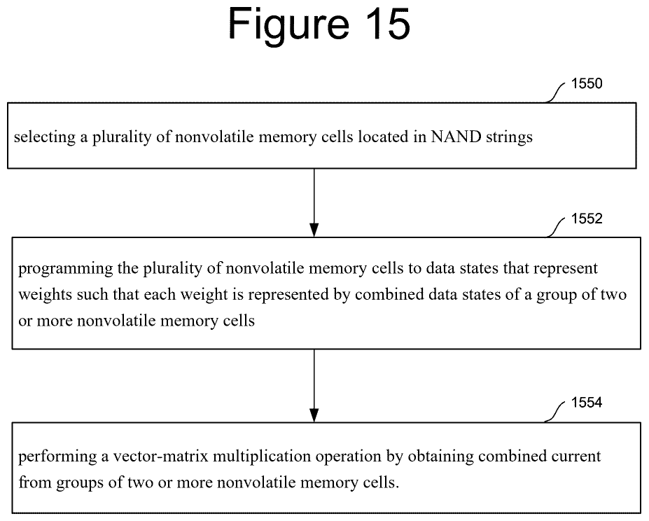

FIG. 15 shows an example of a method that includes selecting a plurality of nonvolatile memory cells located in NAND strings 1550, programming the plurality of nonvolatile memory cells to data states that represent weights such that each weight is represented by combined data states of a group of two or more nonvolatile memory cells 1552 (e.g., as illustrated in tables 12B-D) and performing a matrix multiplication operation by obtaining combined current from groups of two or more nonvolatile memory cells 1554 (e.g., as illustrated by FIG. 6.

Control circuits (e.g., all or a portion of system control logic 260, all or a portion of row control circuitry 220, all or a portion of column control circuitry 210) may be connected to components of memory structures 800 and 900 as previously described in order to apply suitable voltages on, for example, word lines and bit lines, to read and write memory cells in groups. Such control circuits may be considered an example of means for storing weights in the nonvolatile memory cells, each individual weight stored by a combination of data states of two or more nonvolatile memory cells.

One embodiment includes a nonvolatile storage apparatus. The nonvolatile storage apparatus includes nonvolatile memory cells; bit lines connected to the nonvolatile memory cells; and one or more control circuits connected to the nonvolatile memory cells and the bit lines. The one or more control circuits are configured to store weights in the nonvolatile memory cells, each individual weight stored by a group of two or more nonvolatile memory cells.

In one example implementation, the one or more control circuits are configured to program each nonvolatile memory cell to three or more data states and an individual weight is represented by the combination of the states of at least a first nonvolatile memory cell and a second nonvolatile memory cell of the group.

In one example implementation, the first nonvolatile memory cell is located in a first NAND string connected to a first bit line and the second nonvolatile memory cell is located in a second NAND string connected to a second bit line.

In one example implementation, the one or more control circuits are further configured to add current through the first bit line and current through the second bit line to obtain a combined current in a vector-matrix multiplication operation.

In one example implementation, the first nonvolatile memory cell is located in a first NAND string connected to a bit line and the second nonvolatile memory cell is located in a second NAND string connected to the bit line.

In one example implementation, the one or more control circuits are configured to obtain a bit line current through the bit line as an output of a vector-matrix multiplication operation.

In one example implementation, each nonvolatile memory cell is programmable to four data states, nonvolatile memory cells are configured as pairs of nonvolatile memory cells consisting of a first nonvolatile memory cell and a second nonvolatile memory cell, each individual weight stored by a combined data state of a pair of nonvolatile memory cells that is selected from seven combined data states.

In one example implementation, each data state corresponds to a threshold voltage range and threshold voltage ranges of the four data states are unequally spaced apart.

In one example implementation, the nonvolatile memory cells and the bit lines are located on a memory die and the one or more control circuits are located on a control die that is bonded to the memory die to form an integrated memory assembly.

In one example implementation, the nonvolatile memory cells are arranged in vertical NAND strings in a 3D NAND memory structure and the bit lines extend across and connect to multiple vertical NAND strings.

One embodiment includes a method, comprising: selecting a plurality of nonvolatile memory cells located in NAND strings; programming the plurality of nonvolatile memory cells to data states that represent weights such that each weight is represented by combined data states of a group of two or more nonvolatile memory cells; and performing a vector-matrix multiplication operation by obtaining combined current from groups of two or more nonvolatile memory cells.

In one example implementation, the method further comprises applying select voltages on select gates corresponding to the plurality of nonvolatile memory cells to provide an input vector for the vector-matrix multiplication operation.

In one example implementation, the method further comprises applying read voltages on selected word lines coupled to the NAND strings and applying pass voltages on non-selected word lines coupled to the NAND strings to select the plurality of nonvolatile memory cells for vector-matrix multiplication.

In one example implementation, the method further comprises adding at least a first current from a first bit line and a second current from a second bit line to obtain a combined current for a group of two or more nonvolatile memory cells.

In one example implementation, the method further comprises measuring current through a bit line while a group of two or more NAND strings that are connected to the bit line and that contain the two or more nonvolatile memory cells of the group are selected to obtain a combined current for the group of two or more nonvolatile memory cells.

In one example implementation, the method further comprises applying read voltages to selected word lines coupled to the group of two or more nonvolatile memory cells while applying pass voltages to unselected word lines coupled to other nonvolatile memory cells in the group of two or more NAND strings to obtain the combined current.

In one example implementation, each group consists of a first nonvolatile memory cell and a second nonvolatile memory cell and the programming includes programming the first nonvolatile memory cell to a first data state selected from four data states, programming the second nonvolatile memory cell to a second data state selected from the four data states, the combined first and second data states representing a combined data state from seven combined data states.

One embodiment includes a memory system, comprising: a three dimensional NAND memory structure having bit lines and nonvolatile memory cells connected in series to form NAND strings connected to the bit lines; and means for storing weights in the nonvolatile memory cells, each individual weight stored by a combination of data states of two or more nonvolatile memory cells.

In one example implementation, the three dimensional NAND memory structure is located on a memory die and the means for storing weights is located on a control die that is bonded to the memory die to form an integrated memory assembly.

For purposes of this document, reference in the specification to “an embodiment,” “one embodiment,” “some embodiments,” or “another embodiment” may be used to describe different embodiments or the same embodiment.

For purposes of this document, a connection may be a direct connection or an indirect connection (e.g., via one or more other parts). In some cases, when an element is referred to as being connected or coupled to another element, the element may be directly connected to the other element or indirectly connected to the other element via one or more intervening elements. When an element is referred to as being directly connected to another element, then there are no intervening elements between the element and the other element. Two devices are “in communication” if they are directly or indirectly connected so that they can communicate electronic signals between them.

For purposes of this document, the term “based on” may be read as “based at least in part on.”

For purposes of this document, without additional context, use of numerical terms such as a “first” object, a “second” object, and a “third” object may not imply an ordering of objects but may instead be used for identification purposes to identify different objects.

For purposes of this document, the term “set” of objects may refer to a “set” of one or more of the objects.

The foregoing detailed description has been presented for purposes of illustration and description. It is not intended to be exhaustive or to limit to the precise form disclosed. Many modifications and variations are possible in light of the above teaching. The described embodiments were chosen in order to best explain the principles of the proposed technology and its practical application, to thereby enable others skilled in the art to best utilize it in various embodiments and with various modifications as are suited to the particular use contemplated. It is intended that the scope be defined by the claims appended hereto.

What is claimed is:

1. A nonvolatile storage apparatus, comprising:
nonvolatile memory cells;
bit lines connected to the nonvolatile memory cells; and
one or more control circuits connected to the nonvolatile memory cells and the bit lines, the one or more control circuits are configured to store weights in the nonvolatile memory cells, each individual weight stored by a group of two or more nonvolatile memory cells.

2. The nonvolatile storage apparatus of claim 1, wherein the one or more control circuits are configured to program each nonvolatile memory cell to three or more data states and an individual weight is represented by the combination of the states of at least a first nonvolatile memory cell and a second nonvolatile memory cell of the group.

3. The nonvolatile storage apparatus of claim 2, wherein the first nonvolatile memory cell is located in a first NAND string connected to a first bit line and the second nonvolatile memory cell is located in a second NAND string connected to a second bit line.

4. The nonvolatile storage apparatus of claim 3, wherein the one or more control circuits are further configured to add current through the first bit line and current through the second bit line to obtain a combined current in a vector-matrix multiplication operation.

5. The nonvolatile storage apparatus of claim 2, wherein the first nonvolatile memory cell is located in a first NAND string connected to a bit line and the second nonvolatile memory cell is located in a second NAND string connected to the bit line.

6. The nonvolatile storage apparatus of claim 5, wherein the one or more control circuits are configured to obtain a bit line current through the bit line as an output of a vector-matrix multiplication operation.

7. The nonvolatile storage apparatus of claim 1, wherein each nonvolatile memory cell is programmable to four data states, nonvolatile memory cells are configured as pairs of nonvolatile memory cells consisting of a first nonvolatile memory cell and a second nonvolatile memory cell, each individual weight stored by a combined data state of a pair of nonvolatile memory cells that is selected from seven combined data states.

8. The nonvolatile storage apparatus of claim 7, wherein each data state corresponds to a threshold voltage range and threshold voltage ranges of the four data states are unequally spaced apart.

9. The nonvolatile storage apparatus of claim 1, wherein the nonvolatile memory cells and the bit lines are located on a memory die and the one or more control circuits are located on a control die that is bonded to the memory die to form an integrated memory assembly.

10. The nonvolatile storage apparatus of claim 1, wherein the nonvolatile memory cells are arranged in vertical NAND strings in a 3D NAND memory structure and the bit lines extend across and connect to multiple vertical NAND strings.

11. A method, comprising:
selecting a plurality of nonvolatile memory cells located in NAND strings;
programming the plurality of nonvolatile memory cells to data states that represent weights such that each weight is represented by combined data states of a group of two or more nonvolatile memory cells; and
performing a vector-matrix multiplication operation by obtaining combined current from groups of two or more nonvolatile memory cells.

12. The method of claim 11, further comprising applying select voltages on select gates corresponding to the plurality of nonvolatile memory cells to provide an input vector for the vector-matrix multiplication operation.

13. The method of claim 12, further comprising applying read voltages on selected word lines coupled to the NAND strings and applying pass voltages on non-selected word lines coupled to the NAND strings to select the plurality of nonvolatile memory cells for vector-matrix multiplication.

14. The method of claim 11, further comprising adding at least a first current from a first bit line and a second current from a second bit line to obtain a combined current for a group of two or more nonvolatile memory cells.

15. The method of claim 11, further comprising measuring current through a bit line while a group of two or more NAND strings that are connected to the bit line and that contain the two or more nonvolatile memory cells of the group are selected to obtain a combined current for the group of two or more nonvolatile memory cells.

16. The method of claim 15, further comprising applying read voltages to selected word lines coupled to the group of two or more nonvolatile memory cells while applying pass voltages to unselected word lines coupled to other nonvolatile memory cells in the group of two or more NAND strings to obtain the combined current.

17. The method of claim 11, wherein each group consists of a first nonvolatile memory cell and a second nonvolatile memory cell and the programming includes programming the first nonvolatile memory cell to a first data state selected from four data states, programming the second nonvolatile memory cell to a second data state selected from the four data states, the combined first and second data states representing a combined data state from seven combined data states.

18. The method of claim 17, further comprising:
determining for each weight to be programmed a first data state to program the first nonvolatile memory cell and a second data state to program the second nonvolatile memory cell.

19. A memory system, comprising:
a three dimensional NAND memory structure having bit lines and nonvolatile memory cells connected in series to form NAND strings connected to the bit lines; and
means for storing weights in the nonvolatile memory cells, each individual weight stored by a combination of data states of two or more nonvolatile memory cells.

20. The memory system of claim 19, wherein the three dimensional NAND memory structure is located on a memory die and the means for storing weights is located on a control die that is bonded to the memory die to form an integrated memory assembly.
